(19) United States
(12) Patent Application Publication
(10) Pub. No.: US 2025/0294962 A1
(43) Pub. Date: Sep. 18, 2025

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Mengzhen LI, Hefei (CN); Bin LIU, Kunshan (CN); Xiujian ZHU, Kunshan (CN); Zhiyong DUAN, Kunshan (CN); Hongyu WANG, Hefei (CN)

(73) Assignees: Hefei Visionox Technology Co., Ltd., Hefei (CN); Visionox Technology Inc., Kunshan (CN)

(21) Appl. No.: 19/075,733

(22) Filed: Mar. 10, 2025

(30) Foreign Application Priority Data
Mar. 13, 2024 (CN) 202410288570.9

(51) Int. Cl. H10K 50/19; H10K 59/122; H10K 59/35; H10K 102/00

(52) U.S. Cl. CPC H10K 50/19; H10K 59/122; H10K 59/353; H10K 2102/351

(57) ABSTRACT

Embodiments of the disclosure provide a display panel and a display device. The display panel includes: a substrate, a first electrode layer, a second electrode layer, an isolation structure, and a light-emitting functional layer. The isolation structure is arranged on one side of the substrate and encloses a plurality of defining openings. The isolation structure includes a first part and a second part that are arranged in a stacked manner. The first part is arranged on a side of the second part close to the substrate, and an orthographic projection of the first part on the substrate is located within an orthographic projection of the second part on the substrate. The light-emitting functional layer includes a plurality of light-emitting elements arranged at intervals. The light-emitting element is at least partially arranged in the defining opening, and includes a first stacked structure, a charge generation layer, and a second stacked structure.

### FIELD

The disclosure relates to the field of display equipment, and particularly to a display panel and a display device.

### BACKGROUND ART

Organic light-emitting diodes (OLED) and display panels based on technologies such as light-emitting diodes (LEDs) have been widely applied in various consumer electronics, such as mobile phones, TV set, laptop computers and desktop computers, thanks to their advantages such as high image quality, energy efficiency, slim design and wide application ranges, and have become the mainstream in display devices. However, it is desirable to improve current preparation process for display panels.

### SUMMARY

Embodiments of the disclosure provides a display panel and a display device, aiming to improve the problems of preparation processes for display panels.

An embodiment in a first aspect of the disclosure provides a display panel, including:
a substrate;
a first electrode layer and a second electrode layer arranged on one side of the substrate and disposed opposite each other in a first direction;
an isolation structure arranged on one side of the substrate and enclosing a plurality of defining openings, the isolation structure including a first part and a second part that are arranged in a stacked manner, the first part being arranged on a side of the second part close to the substrate, and an orthographic projection of the first part on the substrate being located within an orthographic projection of the second part on the substrate; and

The light-emitting functional layer includes a plurality of light-emitting elements arranged at intervals. The light-emitting element is at least partially arranged in the defining opening, and includes a first stacked structure, a charge generation layer and a second stacked structure. The first electrode layer, the first stacked structure, the charge generation layer, the second stacked structure and the second electrode layer are arranged in sequence.

According to implementations in the first aspect of the disclosure, the first stacked structure includes a first light-emitting layer, the second stacked structure includes a second light-emitting layer, the plurality of light-emitting elements include a first light-emitting element and a second light-emitting element, the first light-emitting layer and the second light-emitting layer of the first light-emitting element are configured to emit a first color of light, and the first light-emitting layer and the second light-emitting layer of the second light-emitting element are configured to emit a second color of light; and
the first light-emitting element has a thickness H1 in the first direction, and the second light-emitting element has a thickness H2 in the first direction, where H1≠H2.

According to any one of the above implementations in the first aspect of the disclosure, the first direction is perpendicular to a surface of the substrate.

According to any one of the above implementations in the first aspect of the disclosure, the light-emitting element located between the first electrode layer and the second electrode layer forms a microcavity structure, and the light-emitting element satisfies the following formula:

$$m * 2 π = {ϕ}_{b} + {ϕ}_{t} + ( \frac{4 π * n * H}{λ} )$$

where m≥2, m represents a positive integer, ϕ_{b} represents a reflection phase shift of the first electrode layer, ϕₜ represents a reflection phase shift of the second electrode layer, H represents the thickness of the light-emitting element in the first direction, λ represents a wavelength of emitted light of the light-emitting element, and n represents a refractive index of the light-emitting element.

According to any one of the above implementations in the first aspect of the disclosure, the plurality of light-emitting elements further include a third light-emitting element, the first light-emitting layer and the second light-emitting layer of the third light-emitting element are configured to emit a third color of light, and the second light-emitting element has a thickness H3 in the first direction, where H1, H2 and H3 are not equal.

According to any one of the above implementations in the first aspect of the disclosure, the first light-emitting layer and the second light-emitting layer of the first light-emitting element are configured to emit red light, the first light-emitting layer and the second light-emitting layer of the second light-emitting element are configured to emit green light, and the first light-emitting layer and the second light-emitting layer of the third light-emitting element are configured to emit blue light, where H1>H2>H3.

According to any one of the above implementations in the first aspect of the disclosure, m=2 for the microcavity structures formed by the first light-emitting element, the second light-emitting element and the third light-emitting element.

According to any one of the above implementations in the first aspect of the disclosure, m≥3 for the microcavity structure formed by at least one of the first light-emitting element, the second light-emitting element and the third light-emitting element; and

According to any one of the above implementations in the first aspect of the disclosure, the first light-emitting layer and the second light-emitting layer of the first light-emitting element are configured to emit the red light, the first light-emitting layer and the second light-emitting layer of the second light-emitting element are configured to emit the green light, and the first light-emitting layer and the second light-emitting layer of the third light-emitting element are configured to emit the blue light, m is 2 for the microcavity structures formed by the first light-emitting element and the second light-emitting element, and m is 3 for the microcavity structure formed by the third light-emitting element.

According to any one of the above implementations in the first aspect of the disclosure, a minimum distance between a surface of the first light-emitting layer of the first light-emitting element that is close to the substrate and the first electrode layer is represented by d11, and a minimum distance between a surface of the first light-emitting layer of the second light-emitting element that is close to the substrate and the first electrode layer is represented by d12, where d11≠d12.

According to any one of the above implementations in the first aspect of the disclosure, the plurality of light-emitting elements further include the third light-emitting element, the first light-emitting layer and the second light-emitting layer of the third light-emitting element are configured to emit the third color of light, and a minimum distance between a surface of the first light-emitting layer of the third light-emitting element that is close to the substrate and the first electrode layer is represented by d13, where d11≠d12≠d13.

According to any one of the above implementations in the first aspect of the disclosure, the first light-emitting layer and the second light-emitting layer of the first light-emitting element are configured to emit red light, the first light-emitting layer and the second light-emitting layer of the second light-emitting element are configured to emit green light, and the first light-emitting layer and the second light-emitting layer of the third light-emitting element are configured to emit blue light, where d11>d12>d13.

According to any one of the above implementations in the first aspect of the disclosure, d11 is in the range of 35-80 nm.

According to any one of the above implementations in the first aspect of the disclosure, d12 is in the range of 30-65 nm.

According to any one of the above implementations in the first aspect of the disclosure, d13 is in the range of 25-60 nm.

According to any one of the above implementations in the first aspect of the disclosure, the first stacked structure includes a plurality of first functional layers, the plurality of first functional layers including a first differential functional layer located on a side of the first light-emitting layer close to or away from the substrate, the first differential functional layer of the first light-emitting element having a thickness H4 in the first direction, and the first differential functional layer of the second light-emitting element having a thickness H5 in the first direction, where H4≠H5.

According to any one of the above implementations in the first aspect of the disclosure, the plurality of first functional layers include a hole injection layer, a first hole transport layer, a first emitting prime layer, a first hole blocking layer and a first electron transport layer, the hole injection layer, the first hole transport layer, the first emitting prime layer, the first light-emitting layer, the first hole blocking layer and the first electron transport layer being sequentially arranged in a stacked manner in a direction from the first electrode layer to the second electrode layer.

According to any one of the above implementations in the first aspect of the disclosure, the first differential functional layer is the first hole transport layer and/or the first emitting prime layer.

According to any one of the above implementations in the first aspect of the disclosure, the first differential functional layer is the first emitting prime layer, the first emitting prime layer of the first light-emitting element has a thickness d61, the first hole transport layer of the second light-emitting element has a thickness d62, and the first hole transport layer of the third light-emitting element has a thickness d63, where d61>d62>d63.

According to any one of the above implementations in the first aspect of the disclosure, the first differential functional layer is the first hole transport layer, the first hole transport layer of the first light-emitting element has a thickness d31, the first hole transport layer of the second light-emitting element has a thickness d32, and the first hole transport layer of the third light-emitting element has a thickness d33, where d31>d32>d33.

According to any one of the above implementations in the first aspect of the disclosure, a minimum distance between a surface of the second light-emitting layer of the first light-emitting element that is away from the substrate and the second electrode layer is represented by d21, and a minimum distance between a surface of the second light-emitting layer of the second light-emitting element that is away from the substrate and the second electrode layer is represented by d22, where d21≠d22.

According to any one of the above implementations in the first aspect of the disclosure, the plurality of light-emitting elements further include a third light-emitting element, the first light-emitting layer and the second light-emitting layer of the third light-emitting element are configured to emit a third color of light, and a minimum distance between a surface of the second light-emitting layer of the third light-emitting element that is away from the substrate and the second electrode layer is represented by d23, where d21≠d22≠d23.

According to any one of the above implementations in the first aspect of the disclosure, the first light-emitting layer and the second light-emitting layer of the first light-emitting element are configured to emit red light, the first light-emitting layer and the second light-emitting layer of the second light-emitting element are configured to emit green light, and the first light-emitting layer and the second light-emitting layer of the third light-emitting element are configured to emit blue light, where d21>d22>d23.

According to any one of the above implementations in the first aspect of the disclosure, d21 is in the range of 25-60 nm.

According to any one of the above implementations in the first aspect of the disclosure, d21 is in the range of 20-50 nm.

According to any one of the above implementations in the first aspect of the disclosure, d21 is in the range of 15-45 nm.

According to any one of the above implementations in the first aspect of the disclosure, the second stacked structure includes a plurality of second functional layers, the plurality of second functional layers including a second differential functional layer located on a side of the second light-emitting layer close to or away from the substrate, the second differential functional layer of the first light-emitting element having a thickness H6 in the first direction, and the second differential functional layer of the second light-emitting element having a thickness H7 in the first direction, where H6≠H7.

According to any one of the above implementations in the first aspect of the disclosure, the plurality of second functional layers include a second hole transport layer, a second emitting prime layer, a second hole blocking layer and a second electron transport layer, the second hole transport layer, the second emitting prime layer, the second light-emitting layer, the second hole blocking layer and the second electron transport layer being sequentially arranged in a stacked manner in a direction from the first electrode layer to the second electrode layer.

According to any one of the above implementations in the first aspect of the disclosure, the second differential functional layer is the second electron transport layer and/or the second emitting prime layer.

According to any one of the above implementations in the first aspect of the disclosure, the second differential functional layer is the second hole blocking layer, the second hole blocking layer of the first light-emitting element has a thickness d71, the second hole blocking layer of the second light-emitting element has a thickness d72, and the second hole blocking layer of the third light-emitting element has a thickness d73, where d71>d72>d73.

According to any one of the above implementations in the first aspect of the disclosure, the second differential functional layer is the second electron transport layer, the second electron transport layer of the first light-emitting element has a thickness d41, the second electron transport layer of the second light-emitting element has a thickness d42, and the second electron transport layer of the third light-emitting element has a thickness d43, where d41>d42>d43.

According to any one of the above implementations in the first aspect of the disclosure, the charge generation layer of the first light-emitting element has a thickness d51, the charge generation layer of the second light-emitting element has a thickness d52, and the charge generation layer of the third light-emitting element has a thickness d53, where d51≠d52≠d53.

According to any one of the above implementations in the first aspect of the disclosure, a surface of the first electrode layer away from the substrate is a reflective surface, the second electrode layer includes a plurality of second electrode portions, and the plurality of second electrode portions are semi-reflective and semi-transmissive electrodes.

According to any one of the above implementations in the first aspect of the disclosure, the plurality of light-emitting elements include a first light-emitting element and a second light-emitting element, the first light-emitting layer and the second light-emitting layer of the first light-emitting element are configured to emit a first color of light, the first light-emitting layer and the second light-emitting layer of the second light-emitting element are configured to emit a second color of light, the second electrode portion located on one side of the first light-emitting element has a thickness H8 in the first direction, and the second electrode portion located on one side of the second light-emitting element has a thickness H9 in the first direction, where H8≠H9.

According to any one of the above implementations in the first aspect of the disclosure, the thickness of the second electrode portion in the first direction is in the range of 10-21 nm.

According to any one of the above implementations in the first aspect of the disclosure, at least one of the first part and the second part includes a first conductive layer, and an edge of the second electrode portion is in lap joint with the first conductive layer.

According to any one of the above implementations in the first aspect of the disclosure, the display panel further includes:
a capping layer located on a side of the second electrode layer away from the substrate, the capping layer being at least partially arranged in the defining opening.

According to any one of the above implementations in the first aspect of the disclosure, the plurality of light-emitting elements include a first light-emitting element and a second light-emitting element, the first light-emitting layer and the second light-emitting layer of the first light-emitting element are configured to emit a first color of light, the first light-emitting layer and the second light-emitting layer of the second light-emitting element are configured to emit a second color of light, the capping layer located on one side of the first light-emitting element has a thickness H10 in the first direction, and the capping layer located on one side of the second light-emitting element has a thickness H11 in the first direction, where H10≠H11.

According to any one of the above implementations in the first aspect of the disclosure, the plurality of light-emitting elements further include a third light-emitting element, the first light-emitting layer and the second light-emitting layer of the third light-emitting element are configured to emit a third color of light, and the capping layer located on one side of the third light-emitting element has a thickness H12 in the first direction, where H10>H11>H12.

According to any one of the above implementations in the first aspect of the disclosure, the first light-emitting layer and the second light-emitting layer of the first light-emitting element are configured to emit red light, the first light-emitting layer and the second light-emitting layer of the second light-emitting element are configured to emit green light, and the first light-emitting layer and the second light-emitting layer of the third light-emitting element are configured to emit blue light.

According to any one of the above implementations in the first aspect of the disclosure, H10 is in the range of 65-85 nm.

According to any one of the above implementations in the first aspect of the disclosure, H11 is in the range of 60-75 nm.

According to any one of the above implementations in the first aspect of the disclosure, H12 is in the range of 50-65 nm.

According to any one of the above implementations in the first aspect of the disclosure, the display panel further includes:
a filter layer located on a side of the second electrode layer away from the substrate and including a plurality of filter portions, an orthographic projection of the plurality of filter portions on the substrate overlapping with an orthographic projection of the light-emitting functional layer on the substrate.

According to any one of the above implementations in the first aspect of the disclosure, the filter layer further includes a light blocking portion arranged to space apart adjacent filter portions, an orthographic projection of the light blocking portion on the substrate falling within an orthographic projection of the isolation structure on the substrate.

According to any one of the above implementations in the first aspect of the disclosure, the isolation structure further includes a pixel defining layer arranged on a side of the first part away from the second part, the pixel defining layer including a plurality of pixel openings, and the light-emitting element being at least partially arranged in the pixel opening.

According to any one of the above implementations in the first aspect of the disclosure, the isolation structure is arranged on a side of the pixel defining layer away from the substrate, and an orthographic projection of the pixel opening on the substrate is located within an orthographic projection of the defining opening on the substrate.

According to any one of the above implementations in the first aspect of the disclosure, the display panel further includes an encapsulation layer located on a side of the second electrode layer away from the substrate, an edge of the encapsulation layer being at least in lap joint with the isolation structure, or the encapsulation layer covering a side of the isolation structure away from the substrate.

According to any one of the above implementations in the first aspect of the disclosure, the isolation structure is in the form of a grid and is arranged to space apart adjacent light-emitting elements.

According to any one of the above implementations in the first aspect of the disclosure, the first part is electrically connected to the second electrode layer.

According to any one of the above implementations in the first aspect of the disclosure, the area of an orthographic projection of a surface, away from the substrate, of the second part on the substrate is less than the area of an orthographic projection of a surface, close to the substrate, of the second part on the substrate.

According to any one of the above implementations in the first aspect of the disclosure, the cross-sectional area of the second part gradually decreases in a direction away from the substrate.

According to any one of the above implementations in the first aspect of the disclosure, the area of an orthographic projection of a surface, away from the substrate, of the first part on the substrate is less than the area of the orthographic projection of the surface, close to the substrate, of the second part on the substrate.

According to any one of the above implementations in the first aspect of the disclosure, the cross-sectional area of the first part gradually decreases in the direction away from the substrate.

According to any one of the above implementations in the first aspect of the disclosure, the isolation structure includes a third part is located on a side of the first part close to the substrate, and the orthographic projection of the first part on the substrate is located within an orthographic projection of the third part on the substrate.

According to any one of the above implementations in the first aspect of the disclosure, the third part is electrically connected to the second electrode layer.

An embodiment in a second aspect of the disclosure further provides a display panel, including:
a substrate;
a first electrode layer and a second electrode layer arranged on one side of the substrate and disposed opposite each other in a first direction;
a light-emitting functional layer including a pixel defining layer and a plurality of light-emitting elements arranged at intervals, the pixel defining layer comprising a plurality of pixel openings, and the plurality of light-emitting elements being at least partially arranged in the pixel opening, wherein at least one of the plurality of light-emitting element includes a first stacked structure, a charge generation layer and a second stacked structure, the first electrode layer, the first stacked structure, the charge generation layer, the second stacked structure and the second electrode layer are arranged in sequence, the first stacked structure includes a first light-emitting layer, and the second stacked structure includes a second light-emitting layer; the plurality of light-emitting elements includes a first light-emitting element and a second light-emitting element, the first light-emitting layer and the second light-emitting layer of the first light-emitting element are configured to emit a first color of light, and the first light-emitting layer and the second light-emitting layer of the second light-emitting element are configured to emit a second color of light; and
a minimum distance between a surface of the second light-emitting layer of the first light-emitting element that is away from the substrate and the second electrode layer is represented by d21, and a minimum distance between a surface of the second light-emitting layer of the second light-emitting element that is away from the substrate and the second electrode layer is represented by d22, where d21≠d22.

According to any one of the above implementations in the second aspect of the disclosure, the first light-emitting layer and the second light-emitting layer of the first light-emitting element are configured to emit red light, and the first light-emitting layer and the second light-emitting layer of the second light-emitting element are configured to emit green light, where d21>d22.

According to any one of the above implementations in the second aspect of the disclosure, the plurality of light-emitting elements further include a third light-emitting element, the first light-emitting layer and the second light-emitting layer of the third light-emitting element are configured to emit a third color of light, and a minimum distance between a surface of the second light-emitting layer of the third light-emitting element that is away from the substrate and the second electrode layer is represented by d23, where d21>d22>d23.

According to any one of the above implementations in the second aspect of the disclosure, d21 is in the range of 25-60 nm.

According to any one of the above implementations in the second aspect of the disclosure, d22 is in the range of 20-50 nm.

According to any one of the above implementations in the second aspect of the disclosure, d23 is in the range of 15-45 nm.

According to any one of the above implementations in the second aspect of the disclosure, the isolation structure includes a third part is located on a side of the first part close to the substrate, and the orthographic projection of the first part on the substrate is located within an orthographic projection of the third part on the substrate.

According to any one of the above implementations in the second aspect of the disclosure, the display panel further includes an isolation structure, the isolation structure being arranged on a side of the pixel defining layer away from the substrate, and enclosing a plurality of defining openings, an orthographic projection of the defining opening on the substrate at least partially overlapping with an orthographic projection of the pixel opening on the substrate, and the isolation structure including a first part and a second part that are arranged in a stacked manner, wherein the first part is arranged on a side of the second part close to the substrate, and an orthographic projection of the first part on the substrate is located within an orthographic projection of the second part on the substrate.

An embodiment in a third aspect of the disclosure further provides a display panel, including:
a substrate;
a first electrode layer and a second electrode layer arranged on one side of the substrate and disposed opposite each other in a first direction;
a pixel defining layer arranged on one side of the substrate and comprising a plurality of pixel openings, the pixel opening including a fourth part and a fifth part that are arranged in a stacked manner, the fourth part being arranged on a side of the fifth part close to the substrate, and an orthographic projection of the fourth part on the substrate being located within an orthographic projection of the fifth part on the substrate; and
a light-emitting functional layer including a plurality of light-emitting elements arranged at intervals, the light-emitting element being at least partially arranged in the pixel opening and including a first stacked structure, a charge generation layer and a second stacked structure, and the first electrode layer, the first stacked structure, the charge generation layer, the second stacked structure and the second electrode layer being arranged in sequence.

An embodiment in a fourth aspect of the disclosure further provides a display device, including a display panel according to any one of the above embodiments in the first aspect, the second aspect and the third aspect.

In the display panel provided by the embodiments of the disclosure, by providing the first light-emitting layer and the second light-emitting layer, a single light-emitting element has a prolonged luminous lifetime and increased luminous brightness; and by providing the isolation structure, arranging the first part of the isolation structure on the side of the second part of the isolation structure that is close to the substrate, and making the orthographic projection of the first part on the substrate within the orthographic projection of the second part on the substrate, the first stacked structure, the charge generation layer and the second stacked structure can be prepared without using metal masks, and the procedure and cost of the metal masks are omitted, a preparation process for the display panel is optimized, the production efficiency of the display panel is improved, and the production cost of the display panel is reduced. Since the light-emitting elements for emitting light of different colors are prepared by means of the isolation structure, the thicknesses of layer structures of the light-emitting elements for emitting light of different colors can be adjusted as required to obtain the light-emitting elements having different properties.

### BRIEF DESCRIPTION OF THE DRAWINGS

In order to describe the embodiments of the disclosure more clearly, the drawings required for illustration of the embodiments of the disclosure will be briefly introduced below. The drawings as described below are only for some of the embodiments of the disclosure, and other drawings can also be obtained from these drawings.

FIG. 1 is a structural schematic cross-sectional view of a display panel according to some embodiments of the disclosure;

FIG. 2 is a structural schematic cross-sectional view of a display panel according to some embodiments of the disclosure;

FIG. 3 is a structural schematic cross-sectional view of a display panel according to some embodiments of the disclosure;

FIG. 4 is a structural schematic cross-sectional view of a display panel according to some embodiments of the disclosure;

FIG. 5 is a structural schematic cross-sectional view of a display panel according to some embodiments of the disclosure;

FIG. 6 is a structural schematic cross-sectional view of a display panel according to some embodiments of the disclosure;

FIG. 7 is a structural schematic cross-sectional view of a display panel according to some embodiments of the disclosure;

FIG. 8 is a structural schematic cross-sectional view of a display panel according to some embodiments of the disclosure;

FIG. 9 is a structural schematic cross-sectional view of a display panel according to some embodiments of the disclosure;

FIG. 10 is a structural schematic cross-sectional view of a display panel according to some embodiments of the disclosure;

FIG. 11 is a structural schematic cross-sectional view of a display panel according to some embodiments of the disclosure;

FIG. 12 is a structural schematic cross-sectional view of a display panel according to some embodiments of the disclosure;

FIG. 13 is a structural schematic cross-sectional view of a display panel according to some embodiments of the disclosure;

FIG. 14 is a structural schematic cross-sectional view of a display panel according to some embodiments of the disclosure;

FIG. 15 is a structural schematic cross-sectional view of a display panel according to some embodiments of the disclosure;

FIG. 16 is a structural schematic cross-sectional view of a display panel according to some embodiments of the disclosure;

FIG. 17 is a structural schematic cross-sectional view of a display panel according to some embodiments of the disclosure;

FIG. 18 is a structural schematic cross-sectional view of a display panel according to some embodiments of the disclosure.

### LIST OF REFERENCE SIGNS

1. Substrate; 11. Base substrate; 13. Drive circuit layer; 131. Active layer; 132. Gate; 133. Drain; 137. Source; 135. First plate; 136. Second plate;
2. Isolation structure; 21. First part; 211. First insulation layer; 212. First conductive layer; 22. Second part; 23. Defining opening; 24. Third part;
3. Light-emitting element; 3a. First light-emitting element; 3b. Second light-emitting element; 3c. Third light-emitting element; 31. First stacked structure; 310. First light-emitting layer; 311. Hole injection layer; 312. First hole transport layer; 313. First emitting prime layer; 314. First hole blocking layer; 315. First electron transport layer;
32. Charge generation layer; 33. Second stacked structure; 330. Second light-emitting layer; 331. Second hole transport layer; 332. Second emitting prime layer; 333. Second hole blocking layer; 334. Second electron transport layer;
4. First electrode layer; 41. First electrode portion; 5. Second electrode layer; 51. Second electrode portion; 6. Pixel defining layer; 61. Fourth part; 62. Fifth part; 7. Capping layer; 8. Encapsulation layer; 9. Filter layer; 91. Filter portion; 92. Light blocking portion.

### DETAILED DESCRIPTION OF EMBODIMENTS

Features and exemplary embodiments in various aspects of the disclosure will be described in detail below. In order to make the embodiments of the disclosure clearer, the disclosure will be further described in detail below with reference to the accompanying drawings and specific embodiments. It should be understood that the specific embodiments described herein are merely configured to explain the disclosure and are not configured to limit the disclosure. Embodiments of the disclosure may be implemented without some of these specific details. The following description of the embodiments is merely to provide a better understanding of the disclosure by illustrating examples of the disclosure.

It should be noted that, herein, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, and a process, a method, an article, or a device that includes a list of elements not only includes those elements but also includes other elements that are not listed, or further includes elements inherent to such a process, method, article, or device. If no more limitations are made, an element limited by “comprising/including . . . ” does not exclude other identical elements existing in the process, the method, the article, or the device which includes the element.

It should be understood that in the description of the structure of a component, a layer or region referred as being located “above” or “over” another layer or region may be directly on the other layer or region, or there may be other layers or regions between it and the other layer or region. Moreover, if the component is turned over, the layer or region will be located “below” or “under” the other layer or region.

In order to solve the above problems, the embodiments of the disclosure provide a display panel and a display device. Various embodiments of the display panel and the display device will be illustrated below with reference to the drawings.

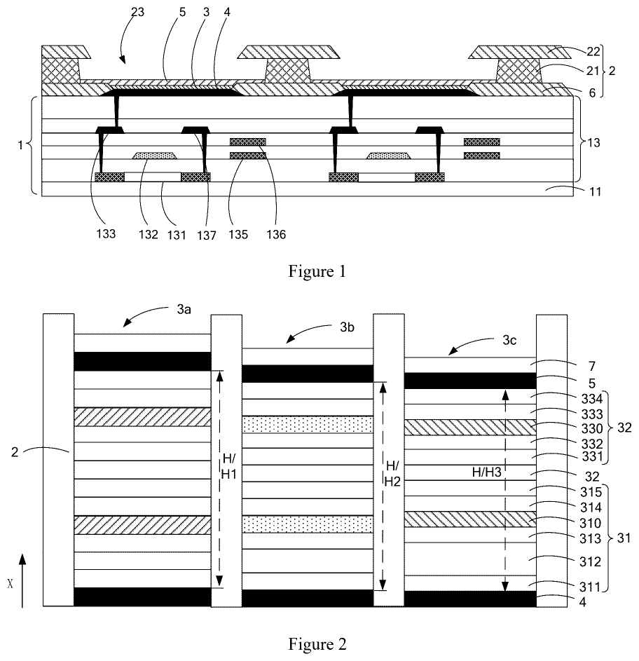

A first aspect of the disclosure provides a display panel. As shown in FIGS. 1 and 2, a display panel includes a substrate 1, a first electrode layer 4, a second electrode layer 5, an isolation structure 2, and a light-emitting functional layer. The first electrode layer 4 and the second electrode layer 5 are arranged on one side of the substrate 1 and opposite each other in a first direction X. The isolation structure 2 is arranged on one side of the substrate 1, the isolation structure 2 encloses a plurality of defining openings 23, and the isolation structure 2 includes a first part 21 and a second part 22 that are arranged in a stacked manner. The first part 21 is arranged on a side of the second part 22 close to the substrate 1, and an orthographic projection of the first part 21 on the substrate 1 is located within an orthographic projection of the second part 22 on the substrate 1. The light-emitting functional layer includes a plurality of light-emitting elements 3 arranged at intervals. The light-emitting element is at least partially arranged in the defining opening 23, and includes a first stacked structure 31, a charge generation layer 32, and a second stacked structure 33. The first electrode layer 4, the first stacked structure 31, the charge generation layer 32, the second stacked structure 33 and the second electrode layer 5 are arranged in sequence. Reference can be made to relevant contents of the isolation structure recited in Chinese Patents No. PCT/CN2023/134518, 202310771071.0, 202311117143.6, 202310759370.2, 202310771124.9, 202311499823.9 and 202310692671.8.

The embodiments of the disclosure provide a display panel, which may be an organic light emitting diode (OLED) display panel.

In the display panel provided in the embodiments of the disclosure, the substrate 1 may not only provide a supporting force for the isolation structure 2 but also provide an electrical signal for the light-emitting functional layer. The substrate 1 may be configured in various forms. In some embodiments, the substrate 1 may include a base substrate 11 and a drive circuit layer 13 arranged on the base substrate 11. The drive circuit layer 13 may include a pixel drive circuit, and a plurality of conductive layers arranged in a stacked manner. By way of example, the pixel drive circuit arranged on the drive circuit layer 13 includes a transistor and a storage capacitor. The transistor includes an active layer 131, a gate 132, a drain 133, and a source 137. The storage capacitor includes a first plate 135 and a second plate 136. As an example, the gate 132 and the first plate 135 may be located in the same conductive layer, the second plate 136 may be located in another conductive layer, and the drain 133 and the source 137 may be located in still another conductive layer.

One of the first electrode layer 4 and the second electrode layer 5 may serve as an anode electrode, and the other may serve as a cathode electrode. The first electrode layer 4, the first stacked structure 31, the charge generation layer 32, the second stacked structure 33 and the second electrode layer 5 may be sequentially laminated in a contact manner, to achieve electrical conduction between the first electrode layer 4, the first stacked structure 31, the charge generation layer 32, the second stacked structure 33 and the second electrode layer 5, for driving the light-emitting element 3 to emit light. In one embodiment, the first electrode layer 4 is an anode electrode, and the second electrode layer 5 is a cathode electrode.

The first stacked structure 31, the charge generation layer 32 and the second stacked structure 33 may form a laminated light-emitting structure. Under the drive of the first electrode layer 4 and the second electrode layer 5, a first light-emitting layer 310 in the first stacked structure 31 and a second light-emitting layer 330 in the second stacked structure 33 can jointly emit light, and by stacking the light-emitting layers for emitting light of the same color, the display panel can have a prolonged service life and increased luminous brightness. The light-emitting element 3 may be a red light-emitting element, a blue light-emitting element, or a green light-emitting element, the first light-emitting layer 310 and the second light-emitting layer 330 of the red light-emitting element are configured to emit red light, the first light-emitting layer 310 and the second light-emitting layer 330 of the blue light-emitting element are configured to emit blue light, the first light-emitting layer 310 and the second light-emitting layer 330 of the green light-emitting element are configured to emit green light, and the light-emitting elements 3 of other colors may be configured by analogy.

The charge generation layer (CGL) is arranged between the first stacked structure 31 and the second stacked structure 33 to supply electrons to one of the first stacked structure 31 and the second stacked structure 33 and to supply holes to the other.

In order to enable the display panel to emit light of different colors, it is necessary to prepare light-emitting elements 3 for emitting light of different colors, and the isolation structure 2 and/or a provided pixel defining layer 6 may be arranged to space apart the individual light-emitting elements 3. The light-emitting elements 3 for emitting light of different colors can be prepared stepwise, that is, a plurality of first light-emitting elements 3a for emitting a first color of light are first prepared, a plurality of second light-emitting elements 3b for emitting a second color of light are then prepared, and so on, until all the light-emitting elements 3 for emitting light of different colors are prepared.

The isolation structure 2 encloses the defining openings 23, the isolation structure 2 includes a first part 21 and a second part 22 that are arranged in a stacked manner, and an orthographic projection of the first part 21 on the substrate 1 is located within an orthographic projection of the second part 22 on the substrate 1, and an end of the isolation structure 2 away from the substrate 1 has a larger cross-sectional area than an end of the isolation structure 2 close to the substrate 1. In a direction from the isolation structure 2 to the substrate 1, the second part 22 shields the entirety of the first part 21. The number of defining openings 23 may correspond to the number of light-emitting elements 3 on a one-to-one basis.

When the light-emitting elements 3 are prepared, a material A used for preparing the light-emitting elements 3 may cover the isolation structure 2 by means of evaporation technology. Since the second part 22 shields the first part 21, the material A used for preparing the light-emitting elements 3 has a large drop at an edge of the second part 22, and it is difficult to connect the material A falling into the defining opening 23 and the material A falling on the second part 22. Accordingly, breakage occurs, and pieces of material A arranged at intervals are formed in or below adjacent defining openings 23. The material A falling on the second part 22 may be removed as required. Compared with the prior art that a light-emitting functional layer is prepared by means of mask evaporation, in the disclosure, by providing the first part 21 and the second part 22, the spaced light-emitting elements 3 can be prepared without using a mask, and the cost of preparing the mask is omitted. Compared with the light-emitting functional layer prepared by preparing a high-precision mask for evaporation, it is easier to directly prepare a high-precision isolation structure 2, and the structure of the display panel provided by the disclosure has low requirements for a preparation process, and the prepared display panel has good consistency. The material A may be an indium-containing complex for preparing the first light-emitting layer 310 and the second light-emitting layer 330 and may also be a material for preparing the charge generation layer 32.

Orthographic projections, on the substrate 1, of the plurality of first light-emitting layers 310 prepared by means of the isolation structure 2 are arranged at intervals, orthographic projections, on the substrate 1, of the plurality of second light-emitting layers 330 prepared by means of the isolation structure 2 are arranged at intervals, and orthographic projections, on the substrate 1, of the plurality of charge generation layers 32 prepared by means of the isolation structure 2 are arranged at intervals. The orthographic projections may be projections in the first direction X. The light-emitting element 3 may further include other layer structures than the first light-emitting layer 310, the second light-emitting layer 330 and the charge generation layer 32, and all the first light-emitting layer 310, the second light-emitting layer 330, the charge generation layer 32 and the other layer structures of the light-emitting element 3 may be prepared by means of the isolation structure 2. Orthographic projections of the other layer structures of the light-emitting element 3 on the substrate 1 are also spaced in a matrix. When different layer structures are prepared, the thicknesses of the prepared layer structures can be adjusted as required, and when the same layer structures of different light-emitting elements 3 are prepared, the thicknesses of the same layer structures of the different light-emitting elements 3 can also be adjusted as required to enrich the properties of the different light-emitting elements 3.

In the embodiments provided by the disclosure, by providing the first light-emitting layer 310 and the second light-emitting layer 330, a single light-emitting element 3 has a prolonged luminous lifetime and increased luminous brightness; and by providing the isolation structure 2, arranging the first part 21 of the isolation structure 2 on the side of the second part 22 of the isolation structure 2 that is close to the substrate 1, and making the orthographic projection of the first part 21 on the substrate 1 within the orthographic projection of the second part 22 on the substrate 1, the first stacked structure 31, the charge generation layer 32 and the second stacked structure 33 can be prepared without using metal masks, and the procedure and cost of the metal masks are omitted, a preparation process for the display panel is optimized, the production efficiency of the display panel is improved, and the production cost of the display panel is reduced. Since the light-emitting elements 3 for emitting light of different colors are prepared by means of the isolation structure 2, the thicknesses of layer structures of the light-emitting elements 3 for emitting light of different colors can be adjusted as required to obtain the light-emitting elements 3 having different properties.

In some embodiments, the first stacked structure 31 includes a first light-emitting layer 310, the second stacked structure 33 includes a second light-emitting layer 330, the plurality of light-emitting elements 3 include a first light-emitting element 3a and a second light-emitting element 3b, the first light-emitting layer 310 and the second light-emitting layer 330 of the first light-emitting element 3a are configured to emit a first color of light, and the first light-emitting layer 310 and the second light-emitting layer 330 of the second light-emitting element 3b are configured to emit a second color of light.

The first light-emitting element 3a has a thickness H1 in the first direction X, and the second light-emitting element 3b has a thickness H2 in the first direction X, where H1≠H2.

The first color of light and the second color of light may be any two of red light, blue light and green light, or may be light of other colors except the red light, the blue light and the green light. By setting H1≠H2, the first light-emitting element 3a and the second light-emitting element 3b can have different light-emitting properties. For example, by setting H1≠H2, the first light-emitting element 3a and the second light-emitting element 3b can meet the requirements for different microcavity benefits. For example, by setting H1≠H2, the light emitted by the first light-emitting element 3a and the light emitted by the second light-emitting element 3b have different optical paths when exiting the display panel, and the requirements for different light-emitting angles can be met.

In one embodiment, the first direction X is perpendicular to a surface of the substrate 1. The first direction X may also be a thickness direction of the display panel.

In some embodiments, the light-emitting element 3 located between the first electrode layer 4 and the second electrode layer 5 forms a microcavity structure, and the light-emitting element 3 satisfies the following formula:

$$m * 2 π = {ϕ}_{b} + {ϕ}_{t} + ( \frac{4 π * n * H}{λ} )$$

where m≥2, m represents a positive integer, ϕ_{b} represents a reflection phase shift of the first electrode layer, ϕₜ represents a reflection phase shift of the second electrode layer, H represents the thickness of the light-emitting element 3 in the first direction, λ represents a wavelength of the emitted light of the light-emitting element 3, and n represents a refractive index of the light-emitting element 3.

The microcavity structure is a structure that enables the light emitted by the light-emitting element 3 to produce a microcavity effect. The microcavity effect is a resonance phenomenon of the light emitted by the first light-emitting layer 310 and the second light-emitting layer 330 in the light-emitting element 3 that occurs between the first electrode layer 4 and the second electrode layer 5, light waves are repeatedly reflected between the first electrode layer 4 and the second electrode layer 5, and the intensity of light of a specific wavelength is enhanced thanks to phase accumulation of multiple reflections.

The generation of the microcavity effect is related to a distance between the first electrode layer 4 and the second electrode layer 5, that is, the thickness H of the light-emitting element 3 in the first direction X, and is also related to the wavelength of the colored light emitted by the light-emitting element 3 and the refractive index of the light-emitting element 3. Therefore, the thickness H of the light-emitting element 3 in the first direction X and the wavelength λ of the emitted light of the first light-emitting layer 310 (or the wavelength λ of the emitted light of the second light-emitting layer 330) corresponding to the light-emitting element satisfy the above formula, where m represents an order of the microcavity effect. When m is 2, a second-order microcavity is generated; and when m is 3, a third-order microcavity is generated. By adjusting the thicknesses of the light-emitting elements 3, the light-emitting elements 3 for emitting light of different colors can achieve the microcavity effect.

In some embodiments, the plurality of light-emitting elements 3 further include a third light-emitting element 3c, the first light-emitting layer 310 and the second light-emitting layer 330 of the third light-emitting element 3c are configured to emit a third color of light, and the second light-emitting element 3b has a thickness H3 in the first direction X, where H1, H2 and H3 are not equal.

The plurality of light-emitting elements 3 include the first light-emitting element 3a for emitting the first color of light, the second light-emitting element 3b for emitting the second color of light and the third light-emitting element 3c for emitting the third color of light, and the first color of light, the second color of light and the third color of light are different, that is, have different wavelengths. By setting H1, H2 and H3 to be not equal, the thicknesses of the first light-emitting element 3a, the second light-emitting element 3b and the third light-emitting element 3c can all be adjusted as required, to achieve different properties.

In some embodiments, the first light-emitting layer 310 and the second light-emitting layer 330 of the first light-emitting element 3a are configured to emit the red light, the first light-emitting layer 310 and the second light-emitting layer 330 of the second light-emitting element 3b are configured to emit the green light, and the first light-emitting layer 310 and the second light-emitting layer 330 of the third light-emitting element 3c are configured to emit the blue light, where H1>H2>H3.

By setting H1>H2>H3, the light-emitting elements 3 for emitting the red light, the green light and the blue light can all achieve the microcavity effect.

In some embodiments, m=2 for the microcavity structures formed by the first light-emitting element 3a, the second light-emitting element 3b and the third light-emitting element 3c.

By adjusting the thicknesses of the first light-emitting element 3a, the second light-emitting element 3b and the third light-emitting element 3c, the light-emitting elements 3 for emitting the light of different colors can all achieve the second-order microcavity.

In some embodiments, m≥3 for the microcavity structure formed by at least one of the first light-emitting element 3a, the second light-emitting element 3b and the third light-emitting element 3c.

At least one of the first light-emitting element 3a, the second light-emitting element 3b and the third light-emitting element 3c generates a third-order microcavity, and the luminous intensity of the light-emitting elements 3 is increased by means of the third-order microcavity.

In some embodiments, the first light-emitting layer 310 and the second light-emitting layer 330 of the first light-emitting element 3a are configured to emit the red light, the first light-emitting layer 310 and the second light-emitting layer 330 of the second light-emitting element 3b are configured to emit the green light, and the first light-emitting layer 310 and the second light-emitting layer 330 of the third light-emitting element 3c are configured to emit the blue light, m is 2 for the microcavity structure formed by the first light-emitting element 3a and the second light-emitting element 3b, and m is 3 for the microcavity structure of the third light-emitting element 3c.

The light-emitting element 3 for emitting the red light emits the light to generate the second-order microcavity, the light-emitting element 3 for emitting the green light emits the light to generate the second-order microcavity, and the light-emitting element 3 for emitting the blue light emits the light to generate the third-order microcavity. Compared with the third light-emitting element 3c emitting the light to generate the second-order microcavity, the third light-emitting element 3c emitting the light to generate the third-order microcavity can improve the luminous efficiency of the third light-emitting element 3c by 10% or above.

Compared with the layer structures of the light-emitting elements 3 prepared by using metal masks, the same layer structures of different light-emitting elements 3 are prepared to have different thicknesses, and it is necessary to prepare one metal mask corresponding to the layer structures having the same thickness, increasing the preparation cost. For example, the charge generation layer 32 of the first light-emitting element 3a, the charge generation layer 32 of the second light-emitting element 3b and the charge generation layer 32 of the third light-emitting element 3c are prepared to have different thicknesses, and it is necessary to correspondingly provide three metal masks. In the disclosure, by providing the isolation structure 2, the metal masks can be omitted, and the same layer structures of different light-emitting elements 3 can be prepared to have different thicknesses, in order to adaptively form microcavities of desired orders.

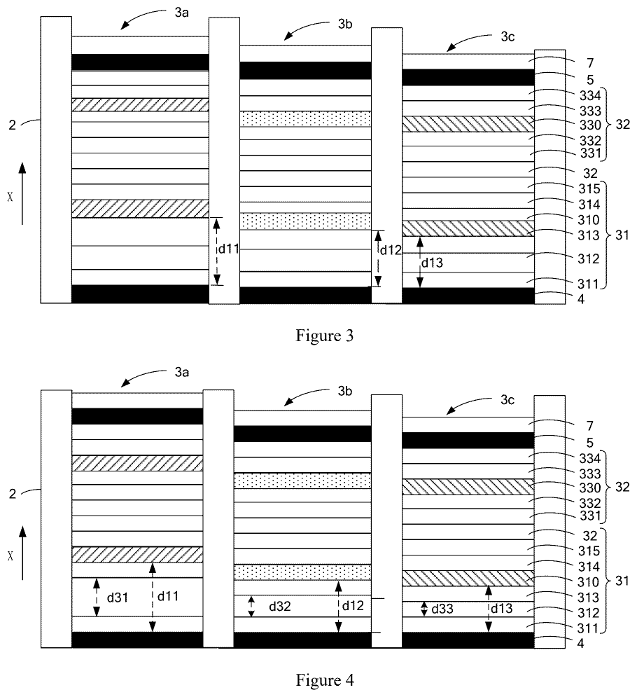

Referring to FIG. 3, in some embodiments, a minimum distance between a surface of the first light-emitting layer 310 of the first light-emitting element 3a that is close to the substrate 1 and the first electrode layer 4 is represented by d11, and a minimum distance between a surface of the first light-emitting layer 310 of the second light-emitting element 3b that is close to the substrate 1 and the first electrode layer 4 is represented by d12, where d11≠d12.

The distances between the first light-emitting layers 310 of different light-emitting elements 3 and the first electrode layer 4 are different, and the light emitted from the first light-emitting layers 310 of the different light-emitting elements 3 is emitted outwardly through different light paths in the display panel, and the first light-emitting layers 310 of the different light-emitting elements 3 have different luminous efficiencies.

A plurality of functional layers may be arranged between the first light-emitting layer 310 and the first electrode layer 4, and one or more functional layers of the different light-emitting elements 3 are prepared to have different thicknesses by means of the isolation structure 2, and thus d11≠d12 is satisfied by adjustment.

In some embodiments, the first stacked structure 31 includes a plurality of first functional layers. The plurality of first functional layers includes a first differential functional layer located on a side of the first light-emitting layer 310 close to or away from the substrate 1. The first differential functional layer of the first light-emitting element 3a has a thickness H4 in the first direction X, and the first differential functional layer of the second light-emitting element 3b has a thickness H5 in the first direction X, where H4≠H5.

The functional layers included in the different light-emitting elements 3 are of the same type and number, and have the same order, and their difference lies in that the functional layers in the same order have different thicknesses. The first differential functional layers of the different light-emitting elements 3 have different thicknesses. The first differential functional layer may be a functional layer arranged on the side of the first light-emitting layer 310 close to the substrate 1, or the first differential functional layer may be a functional layer arranged on the side of the first light-emitting layer 310 away from the substrate 1. One or more first differential functional layers may be included in the plurality of first functional layers. By setting that the first differential functional layers of the different light-emitting elements 3 have different thicknesses, it is possible to enable the different light-emitting elements 3 to have different thicknesses and thus the different light-emitting elements 3 to have different properties.

In some embodiments, the plurality of first functional layers includes a hole injection layer (HIL) 311, a first hole transport layer (HTL) 312, a first emitting prime layer 313, a first hole blocking layer (HBL) 314 and a first electron transport layer (ETL) 315. The hole injection layer 311, the first hole transport layer 312, the first emitting prime layer 313, the first light-emitting layer 310, the first hole blocking layer 314 and the first electron transport layer 315 are sequentially arranged in a stacked manner in a direction from the first electrode layer 4 to the second electrode layer 5.

In some embodiments, the plurality of light-emitting elements 3 further include the third light-emitting element 3c, the first light-emitting layer 310 and the second light-emitting layer 330 of the third light-emitting element 3c are configured to emit the third color of light, and a minimum distance between a surface of the first light-emitting layer 310 of the third light-emitting element 3c that is close to the substrate 1 and the first electrode layer 4 is represented by d13, where d11≠d12≠d13.

By setting d11≠d12≠d13, the emitted light of the first light-emitting layer 310 of the first light-emitting element 3a, the emitted light of the first light-emitting layer 310 of the second light-emitting element 3b and the emitted light of the first light-emitting layer 310 of the third light-emitting element 3c are emitted outwardly through different light paths in the display panel, and the first light-emitting layers 310 of the different light-emitting elements 3 have different luminous efficiencies.

In some embodiments, the first light-emitting layer and the second light-emitting layer of the first light-emitting element 3 are configured to emit the red light, the first light-emitting layer and the second light-emitting layer of the second light-emitting element 3 are configured to emit the green light, and the first light-emitting layer and the second light-emitting layer of the third light-emitting element 3 are configured to emit the blue light, where d11>d12>d13.

Since the wavelength of the red light, the wavelength of the green light and the wavelength of the blue light decrease in sequence, the microcavity effects for the red light, the green light and the blue light can be achieved by correspondingly setting d11>d12>d13.

In some embodiments, d11 is in the range of 35-80 nm.

In some embodiments, d12 is in the range of 30-65 nm.

In some embodiments, d13 is in the range of 25-60 nm.

The different luminous efficiencies can be obtained by changing the distances between the first electrode layer 4 and the first light-emitting layers 310 for respectively emitting the red light, the green light and the blue light. When the first light-emitting layer 310 is configured to emit the red light, d11 is in the range of 35-80 nm, and the first light-emitting layer 310 has good luminous efficiency. When the first light-emitting layer 310 is configured to emit the green light, d12 is in the range of 30-65 nm, and the first light-emitting layer 310 has good luminous efficiency. When the first light-emitting layer 310 is configured to emit the blue light, d13 is in the range of 25-60 nm, and the first light-emitting layer 310 has good luminous efficiency.

When the first differential functional layer may be a functional layer arranged on the side of the first light-emitting layer 310 close to the substrate 1, the first differential functional layer may be one or both of the hole injection layer 311 and the first hole transport layer 312. When the first differential functional layer may be a functional layer arranged on the side of the first light-emitting layer 310 away from the substrate 1, the first differential functional layer may be one or both of the first hole blocking layer 314 and the first electron transport layer 315.

In some embodiments, the first differential functional layer is the first hole transport layer 312 and/or the first emitting prime layer 313.

By adjusting the thickness of the first hole transport layer 312 and/or the thickness of the first emitting prime layer 313, the influence on the electrical properties of each first stacked structure 31 is small, and an adjustable range of the thickness of the first differential functional layer is widened.

Referring to FIG. 4, in one embodiment, the first differential functional layer is the first emitting prime layer 313, the first emitting prime layer 313 of the first light-emitting element 3a has a thickness d61, the first emitting prime layer 313 of the second light-emitting element 3b has a thickness d62, and the first emitting prime layer 313 of the third light-emitting element 3c has a thickness d63, where d61>d62>d63.

It is possible to change only the thickness of the first emitting prime layer 313 of each light-emitting unit while keeping other same functional layers between the first light-emitting layer 310 of each light-emitting element 3 and the first electrode layer 4 consistent in thickness, to achieve different distances between the first light-emitting layers 310 and the first electrode layer 4.

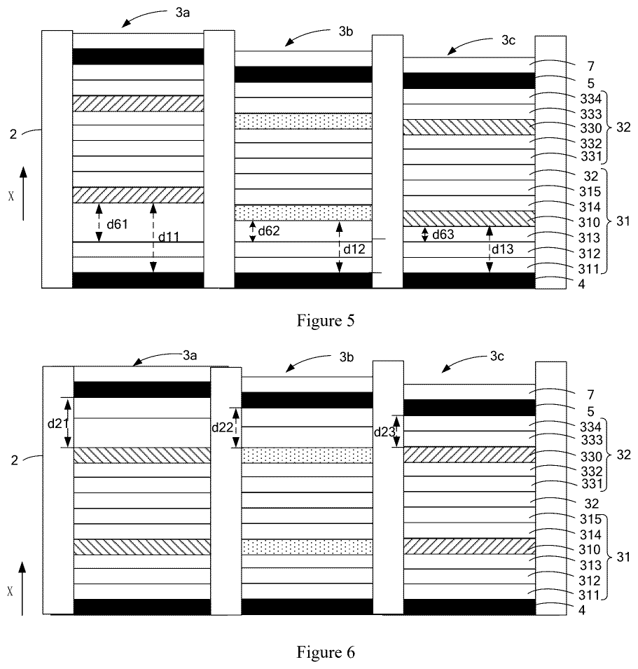

Referring to FIG. 5, in one embodiment, the first differential functional layer is the first hole transport layer 312, the first hole transport layer 312 of the first light-emitting element 3a has a thickness d31, the first hole transport layer 312 of the second light-emitting element 3b has a thickness d32, and the first hole transport layer 312 of the third light-emitting element 3c has a thickness d33, where d31>d32>d33.

It is possible to change only the thickness of the first hole transport layer 312 of each light-emitting unit while keeping other same functional layers between the first light-emitting layer 310 of each light-emitting element 3 and the first electrode layer 4 consistent in thickness, to achieve different distances between the first light-emitting layers 310 and the first electrode layer 4.

Referring to FIG. 6, in some embodiments, a minimum distance between a surface of the second light-emitting layer 330 of the first light-emitting element 3a that is away from the substrate 1 and the second electrode layer 5 is represented by d21, and a minimum distance between a surface of the second light-emitting layer 330 of the second light-emitting element 3b that is away from the substrate 1 and the second electrode layer is represented by d22, where d21≠d22.

In some embodiments, the first light-emitting layer 310 and the second light-emitting layer 330 of the third light-emitting element 3c are configured to emit the third color of light, and a minimum distance between a surface of the second light-emitting layer 310 of the third light-emitting element 3c that is away from the substrate 1 and the second electrode layer 5 is represented by d23, where d21≠d22≠d23.

By setting d21≠d22≠d23, the emitted light of the second light-emitting layer 330 of the first light-emitting element 3a, the emitted light of the second light-emitting layer 330 of the second light-emitting element 3b and the emitted light of the second light-emitting layer 330 of the third light-emitting element 3c are emitted outwardly through different light paths in the display panel, and the first light-emitting layers 310 of the different light-emitting elements 3 have different luminous efficiencies.

In some embodiments, the first light-emitting layer 310 and the second light-emitting layer 310 of the first light-emitting element 3a are configured to emit the red light, the first light-emitting layer 310 and the second light-emitting layer 310 of the second light-emitting element 3b are configured to emit the green light, and the first light-emitting layer 310 and the second light-emitting layer 310 of the third light-emitting element 3c are configured to emit the blue light, where d21>d22>d23.

Since the wavelength of the red light, the wavelength of the green light and the wavelength of the blue light decrease in sequence, the microcavity effects for the red light, the green light and the blue light can be achieved by correspondingly setting d21>d22>d23.

In some embodiments, d21 is in the range of 25-60 nm.

In some embodiments, d22 is in the range of 20-50 nm.

In some embodiments, d23 is in the range of 15-45 nm.

The different luminous efficiencies can be obtained by changing the distances between the second electrode layer 5 and the second light-emitting layers 330 for respectively emitting the red light, the green light and the blue light. When the second light-emitting layer 330 is configured to emit the red light, d21 is in the range of 25-60 nm, and the second light-emitting layer 330 has good luminous efficiency. When the second light-emitting layer 330 is configured to emit the green light, d22 is in the range of 20-50 nm, and the second light-emitting layer 330 has good luminous efficiency. When the second light-emitting layer 330 is configured to emit the blue light, d23 is in the range of 15-45 nm, and the first light-emitting layer 310 has good luminous efficiency. Compared with d23 for the second light-emitting layer 330 configured to emit the green or blue light, d21 for the second light-emitting layer 330 configured to emit the red light being larger facilitates an improvement in the luminous efficiency of the red light.

In some embodiments, the second light-emitting layer 330 of the first light-emitting element 3a is configured to emit the red light, where d21 is in the range of 25-60 nm.

In some embodiments, the second light-emitting layer 330 of the first light-emitting element 3a is configured to emit the green light, where d22 is in the range of 20-50 nm.

In some embodiments, the second light-emitting layer 330 of the first light-emitting element 3a is configured to emit the blue light, where d23 is in the range of 15-45 nm.

In some embodiments, the light-emitting element 3 located between the first electrode layer 4 and the second electrode layer 5 forms a microcavity structure, and the light-emitting element 3 satisfies the following formula:

$$m * 2 π = {ϕ}_{b} + {ϕ}_{t} + \sum ( \frac{4 π {n}_{i} {d}_{i} cos θ}{λ} )$$

where m≥2, m represents a positive integer, ϕ_{b} represents a reflection phase shift of a first electrode, ϕt represents a reflection phase shift of a second electrode, nᵢ
represents a refractive index of an i^{th} functional layer in the light-emitting element 3, dᵢ represents the thickness of the i^{th} functional layer in the light-emitting element 3 in the first direction X, λ represents the wavelength of the emitted light of the light-emitting element 3, and θ represents an included angle formed by the emitted light of the light-emitting element and the first direction.

The distances between the second light-emitting layers 330 of different light-emitting elements 3 and the second electrode layer 5 are different, and the light emitted from the second light-emitting layers 330 of the different light-emitting elements 3 is emitted outwardly through different light paths in the display panel, and the second light-emitting layers 330 of the different light-emitting elements 3 have different luminous efficiencies.

A plurality of functional layers may be arranged between the second light-emitting layer 330 and the second electrode, and one or more functional layers of the different light-emitting elements 3 are prepared to have different thicknesses by means of the isolation structure 2, and thus d21≠d22 is satisfied by adjustment.

In some embodiments, the second stacked structure 33 includes a plurality of second functional layers. The plurality of second functional layers includes a second differential functional layer located on a side of the second light-emitting layer 330 close to or away from the substrate 1. The second differential functional layer of the first light-emitting element 3a has a thickness H6 in the first direction X, and the second differential functional layer of the second light-emitting element 3b has a thickness H7 in the first direction X, where H6≠H7.

The second differential functional layers of the different light-emitting elements 3 have different thicknesses. The second differential functional layer may be a functional layer arranged on the side of the second light-emitting layer 330 close to the substrate 1, or the second differential functional layer may be a functional layer arranged on the side of the second light-emitting layer 330 away from the substrate 1. One or more second differential functional layers may be included in the plurality of second functional layers. By setting that the second differential functional layers of the different light-emitting elements 3 have different thicknesses, it is possible to enable the different light-emitting elements 3 to have different thicknesses and thus the different light-emitting elements 3 to have different properties.

In some embodiments, the plurality of second functional layers includes a second hole transport layer 331, a second emitting prime layer 332, a second hole blocking layer 333 and a second electron transport layer 334, and the second hole transport layer 331, the second emitting prime layer 332. The second light-emitting layer 330, the second hole blocking layer 333 and the second electron transport layer 334 are sequentially arranged in a stacked manner in the direction from the first electrode layer 4 to the second electrode layer 5.

When the second differential functional layer may be a functional layer arranged on a side of the second light-emitting layer 330 close to the substrate 1, the second differential functional layer may be one or both of the second hole transport layer 331 and the second emitting prime layer 332. When the second differential functional layer may be a functional layer arranged on the side of the second light-emitting layer 330 away from the substrate 1, the second differential functional layer may be one or both of the second hole blocking layer 333 and the second electron transport layer 334.

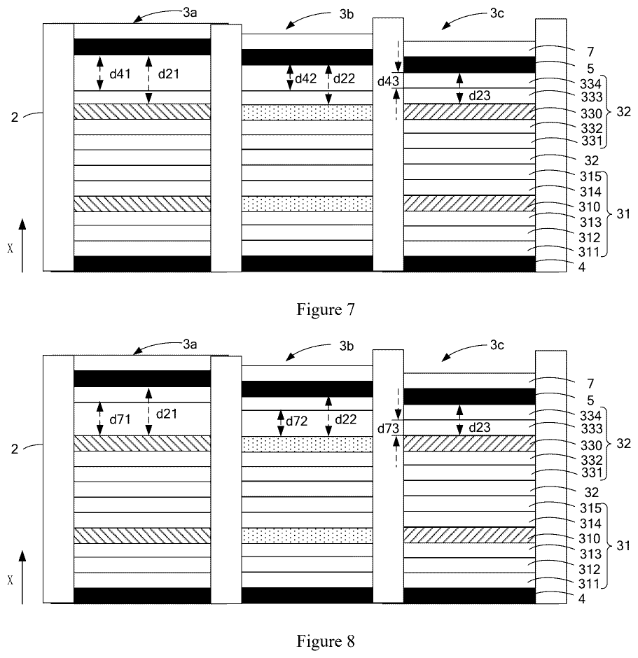

Referring to FIG. 7, in some embodiments, the second differential functional layer is the second hole blocking layer 333 and/or the second electron transport layer 334.

By adjusting the thickness of the second hole blocking layer 333 and/or the thickness of the second electron transport layer 334, the influence on the electrical properties of each second stacked structure 33 is small, and an adjustable range of the thickness of the second differential functional layer is widened.

The second differential functional layer is the second electron transport layer 334, the second electron transport layer 334 of the first light-emitting element 3a has a thickness d41, the second electron transport layer 334 of the second light-emitting element 3b has a thickness d42, and the second electron transport layer 334 of the third light-emitting element 3c has a thickness d43, where d41>d42>d43.

It is possible to change only the thickness of the second electron transport layer 334 in each light-emitting unit while keeping other same functional layers between the second light-emitting layer 330 of each light-emitting element 3 and the second electrode layer 5 consistent in thickness, to achieve different distances between the second light-emitting layers 330 and the second electrode layer 5.

Referring to FIG. 8, the second differential functional layer is the second hole blocking layer 333, the second hole blocking layer 333 of the first light-emitting element 3a has a thickness d71, the second hole blocking layer 333 of the second light-emitting element 3b has a thickness d72, and the second hole blocking layer 333 of the third light-emitting element 3c has a thickness d73, where d71>d72>d73.

It is possible to change only the thickness of the second hole blocking layer 333 in each light-emitting unit while keeping other same functional layers between the second light-emitting layer 330 of each light-emitting element 3 and the second electrode layer 5 consistent in thickness, to achieve different distances between the second light-emitting layers 330 and the second electrode layer 5.

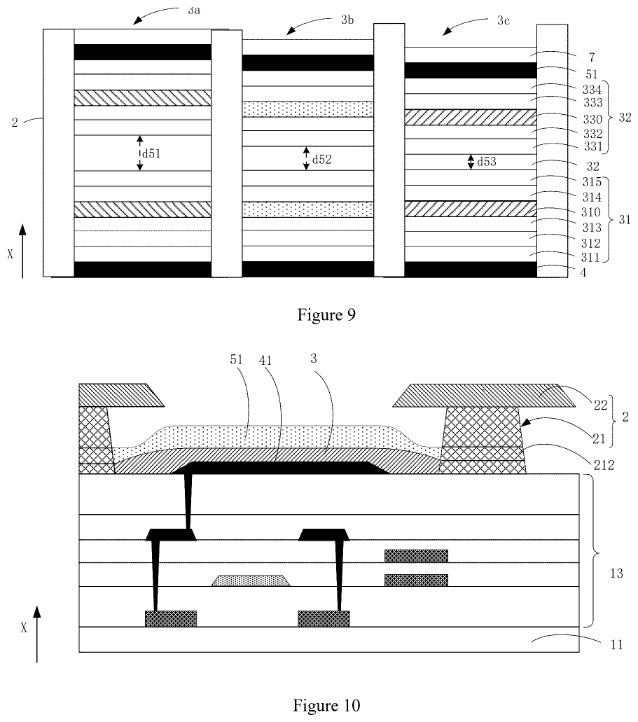

Referring to FIG. 9, in some embodiments, the charge generation layer 32 of the first light-emitting element 3a has a thickness d51, the charge generation layer 32 of the second light-emitting element 3b has a thickness d52, and the charge generation layer 32 of the third light-emitting element 3c has a thickness d53, where d51≠d52≠d53.

In the light-emitting elements 3, the first stacked structures 31 can be kept consistent in thickness, and the second stacked structures 33 can be kept consistent in thickness. By setting d51≠d52≠d53, different thicknesses H of the light-emitting elements 3 are obtained, to adapt to the different wavelengths of the emitted light to achieve the microcavity effect.

Referring to FIG. 10, the first electrode layer 4 may be configured as a light-transmitting electrode as required or may be configured as a non-light-transmitting electrode as required. In some embodiments, a surface of the first electrode layer 4 away from the substrate 1 is a reflective surface, and the second electrode layer 5 includes a plurality of second electrode portions 51. The second electrode portions 51 are semi-reflective and semi-transmissive electrodes.

The first electrode layer 4 may be a surface electrode. That is, the light-emitting elements 3 are jointly electrically connected to the surface electrode, and the surface electrode may provide the same voltage level for the light-emitting elements 3. The first electrode layer 4 may be a point electrode, the first electrode layer 4 includes a plurality of spaced-apart first electrode portions 41. That is, the light-emitting elements 3 are respectively electrically connected to different first electrode portions 41, and the different first electrode portions 41 may provide different voltage levels for the light-emitting elements 3. The different first electrode portions 41 may be insulated and isolated by the pixel defining layer 6 or the isolation structure 2.

The adjacent second electrode portions 51 may form a surface electrode by means of lap joint with the isolation structure 2 or other conductive structures. That is, the light-emitting elements 3 are jointly electrically connected to the surface electrode, and the surface electrode may provide the same voltage level for the light-emitting elements 3. The second electrode layer 5 may be a point electrode, the second electrode layer 5 includes a plurality of second electrode portions 51 arranged at intervals. That is, the light-emitting elements 3 are respectively electrically connected to different second electrode portions 51, and the different second electrode portions 51 may provide different voltage levels for the light-emitting elements 3. The different second electrode portions 51 may be insulated and isolated by the pixel defining layer 6 or the isolation structure 2.

The surface of the first electrode layer 4 away from the substrate 1 is the reflective surface and the emitted light emitted by the light-emitting elements 3 can be reflected by the first electrode layer 4, and the second electrode portion 51 is a semi-reflective and semi-transmissive electrode and the emitted light emitted by the light-emitting element 3 can be partially reflected by the second electrode layer 5 and partially emitted out through the second electrode layer 5. By configuring the surface of the first electrode layer 4 away from the substrate 1 as the reflective surface and the second electrode portion 51 as the semi-reflective and semi-transmissive electrode, there is a basis for creating microcavity benefits between the first electrode layer 4 and the second electrode layer 5.

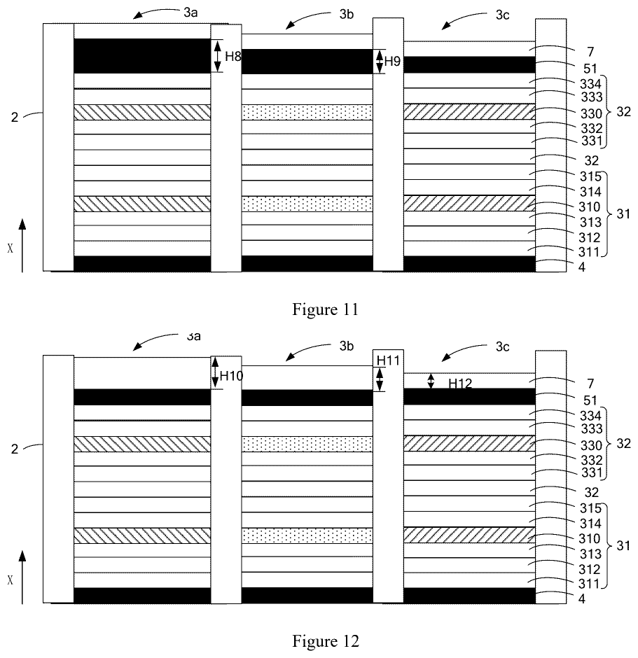

Referring to FIG. 11, in some embodiments, the plurality of light-emitting elements 3 include a first light-emitting element 3a and a second light-emitting element 3b, the first light-emitting layer 310 and the second light-emitting layer 330 of the first light-emitting element 3a are configured to emit a first color of light, the first light-emitting layer 310 and the second light-emitting layer 330 of the second light-emitting element 3b are configured to emit a second color of light, the second electrode portion 51 located on one side of the first light-emitting element 3a has a thickness H8 in the first direction X, and the second electrode portion 51 located on one side of the second light-emitting element 3b has a thickness H9 in the first direction X, where H8≠H9.

The light-emitting elements 3 configured to emit the red light, the blue light and the green light, if the second electrode has different thicknesses, the light-emitting elements 3 for emitting light of different colors have different luminous efficiencies. By setting H8≠H9, the luminous efficiencies of the different light-emitting elements 3 are improved.

In some embodiments, the thickness of the second electrode portion 51 in the first direction X is in the range of 10-21 nm.

In the plurality of light-emitting elements 3 for emitting the red light, the blue light and the green light, the second electrode portions 51 corresponding to at least two light-emitting elements 3 can be set to have different thicknesses. By setting the thickness of the second electrode portion 51 in the first direction X to be in the range of 10-21 nm, the excessively large thickness of the second electrode portion 51 can be avoided, which otherwise affects the thinning of the display panel, and the excessively small thickness of the second electrode portion 51 can also be avoided, which otherwise affects the stability of connection between the second electrode portion 51 and the light-emitting element 3, to improve the luminous efficiency of the light-emitting element 3.

In some embodiments, at least one of the first part 21 and the second part 22 includes a first conductive layer 212, and an edge of the second electrode portion 51 is in lap joint with the first conductive layer 212. That is, the first part 21 is electrically connected to the second electrode layer 5.

Adjacent second electrode portions 51 may be electrically connected to each other by means of the first conductive layer 212, and the second electrode portions 51 and the first conductive layer 212 may jointly form a surface electrode, and the design of a control circuit can be simplified. By setting the thickness of the second electrode portion 51 in the first direction X to be in the range of 10-21 nm, the stable lap joint between the edge of the second electrode portion 51 and the first conductive layer 212 can also be ensured.

Referring to FIG. 12, in some embodiments, the display panel further includes a capping layer 7 (CPL). The capping layer 7 is located on a side of the second electrode layer 5 away from the substrate 1, and the capping layer 7 is at least partially arranged in the defining opening 23.

The capping layer 7 can protect the light-emitting element 3 and enhance the capping efficiency, thereby helping to prolong the service life of a display surface and improving the stability thereof. The capping layer 7 may also be divided into a plurality of spaced-apart blocks by means of the isolation structure 2. The plurality of spaced-apart blocks are respectively formed by means of the isolation structure 2.

In some embodiments, the plurality of light-emitting elements 3 include a first light-emitting element 3a and a second light-emitting element 3b, the first light-emitting layer 310 and the second light-emitting layer 330 of the first light-emitting element 3a are configured to emit a first color of light, the first light-emitting layer 310 and the second light-emitting layer 330 of the second light-emitting element 3b are configured to emit a second color of light, the capping layer 7 located on one side of the first light-emitting element 3a has a thickness H10 in the first direction X, and the capping layer 7 located on one side of the second light-emitting element 3b has a thickness H11 in the first direction X, where H10≠H11.

If the capping layer 7 corresponding to the light-emitting elements 3 for emitting the red light, the blue light and the green light has different thicknesses, the light-emitting elements 3 for emitting light of different colors have different luminous efficiencies. By setting H10≠H11, the different light-emitting elements 3 have the luminous efficiencies.

In some embodiments, the plurality of light-emitting elements 3 further include a third light-emitting element 3c, and the first light-emitting layer 310 and the second light-emitting layer 330 of the third light-emitting element 3c are configured to emit a third color of light. The first light-emitting layer 310 and the second light-emitting layer 330 of the first light-emitting element 3a are configured to emit the red light, the first light-emitting layer 310 and the second light-emitting layer 330 of the second light-emitting element 3b are configured to emit the green light, the first light-emitting layer 310 and the second light-emitting layer 330 of the third light-emitting element 3c are configured to emit the blue light, and the capping layer 7 located on one side of the third light-emitting element 3c has a thickness H12 in the first direction X, where H10>H11>H12.

By setting H10>H11>H12, an improvement in the luminous efficiencies of the red light, the green light and the blue light is facilitated.

The excessively thick capping layer 7 will lead to an increase in the overall thickness of the display panel, and the excessively thin capping layer 7 will cause the reduction of the protection capacity to the light-emitting elements 3. In one embodiment, H10 is in the range of 65-85 nm, H11 is in the range of 60-75 nm, and H12 is in the range of 50-65 nm, and the thicknesses of the capping layer 7 are appropriate.

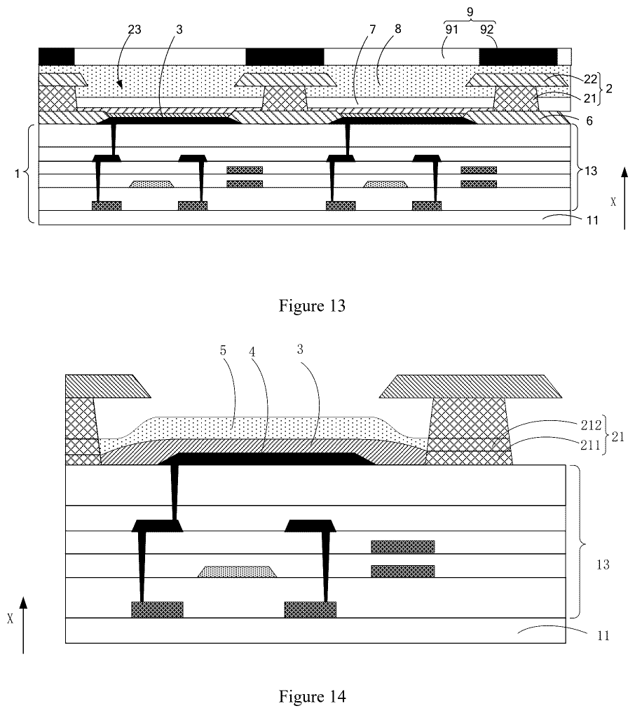

Referring to FIG. 13, in some embodiments, the display panel further includes a filter layer 9. The filter layer 9 is located on the side of the second electrode layer 5 away from the substrate 1, and the filter layer 9 includes a plurality of filter portions 91. An orthographic projection of the filter portion 91 on the substrate 1 overlaps with an orthographic projection of the light-emitting functional layer on the substrate 1.

The light-emitting elements 3 for emitting light of different colors correspond to different filter portions 91. For example, the filter portion 91 corresponding to the light-emitting element 3 for emitting the red light can transmit the red light and block light of other colors than the red light. The filter portion 91 corresponding to the light-emitting element 3 for emitting the green light can transmit the green light and block light of other colors than the green light. The filter portion 91 corresponding to the light-emitting element 3 for emitting the blue light can transmit the blue light and block light of other colors than the blue light.

By providing the filter portions 91, external light can be effectively prevented from entering the display panel, and the color shift problem of the light of all colors at a large viewing angle can also be reduced.

In some embodiments, the filter layer 9 further includes a light blocking portion 92. The light blocking portion 92 is arranged to space apart adjacent filter portions 91, and an orthographic projection of the light blocking portion 92 on the substrate 1 falls within an orthographic projection of the isolation structure 2 on the substrate 1.

The light blocking portion 92 is prepared by a non-light-transmitting material. By providing the light blocking portions 92, the mixture of the light of different colors in the display panel can be reduced.

In some embodiments, the isolation structure 2 further includes a pixel defining layer 6 arranged on a side of the first part 21 away from a second part 22. The pixel defining layer 6 includes pixel openings. The light-emitting element 3 is at least partially arranged in the pixel opening.

The pixel defining layer 6 includes a pixel defining portion enclosing the pixel openings. The light-emitting element 3 may be at least partially arranged in the pixel opening to achieve the luminous display of the display panel, and the pixel opening may be a part of the defining opening.

In some embodiments, an orthographic projection of the pixel opening on the substrate 1 is located within an orthographic projection of the defining opening 23 on the substrate 1.

The first part 21 may be directly arranged on a side of the pixel defining layer 6 away from the substrate 1, and the first part 21 is supported by means of the pixel defining layer 6. An orthographic projection of an opening enclosed by the first parts 21 and an orthographic projection of an opening enclosed by the second parts 22 on the substrate 1 may cover the orthographic projection of the pixel opening on the substrate 1. The area of the opening enclosed by the first parts 21 and the area of the opening enclosed by the second parts 22 are greater than the area of the pixel opening, and the influence of the isolation structure 2 on a light output viewing angle of the light-emitting functional layer can be reduced.

In one embodiment, a plurality of pixel openings are provided, which are distributed at intervals, and the first part 21 may be arranged on at least part of the pixel defining portion between adjacent two pixel openings. In one embodiment, the first part 21 may surround at least part of the pixel opening.

In some embodiments, the display panel further includes an encapsulation layer 8. The encapsulation layer 8 is located on a side of the second electrode away from the substrate 1, and an edge of the encapsulation layer 8 is at least in lap joint with the isolation structure 2, or the encapsulation layer 8 covers a side of the isolation structure 2 away from the substrate 1.

The encapsulation layer 8 may be in contact with a side wall of the isolation structure 2 facing the defining opening 23 or may cover the side of the isolation structure 2 away from the substrate 1. The encapsulation layer 8 can isolate water vapor and the like from entering the light-emitting functional layer and can also avoid or reduce the failure of the light-emitting functional layer caused by a mechanical external force, thus improving the reliability of the display panel.

The encapsulation layer 8 may be made of an inorganic material and/or an organic material. The inorganic material may be specifically silicon nitride, silicon oxide, silicon oxynitride and so on, and the encapsulation layer may be specifically formed by using a chemical vapor deposition (CVD) process. The organic material may be resin or an organic polymer material, and the encapsulation layer may be specifically formed by using an inkjet printing (IJP) process.

In some embodiments, the encapsulation layer 8 is at least partially arranged to space apart the second electrode layer 5 from the first part 21 to avoid or reduce the electrical conduction between the second electrode and the first part 21.

Referring to FIG. 14, in some embodiments, the isolation structure 2 is in the form of a grid, and the isolation structure 2 is arranged to space apart adjacent light-emitting elements 3. In one embodiment, the light-emitting elements 3 correspond to the defining openings 23 on a one-to-one basis.

The isolation structure 2 is arranged to space apart adjacent light-emitting elements 3 to avoid the crosstalk between the adjacent light-emitting elements 3.

In some embodiments, the first part 21 is electrically connected to the second electrode layer 5.

The first part 21 may be wholly or partially prepared by a conductive material, and the first part 21 can be electrically connected to the second electrode layer 5, and the first part 21 can provide a required drive voltage for the second electrode layer 5.

In some embodiments, the first part 21 includes a first insulation layer 211, and the first insulation layer 211 spaces apart the charge generation layers 32 of adjacent light-emitting elements 3.

The charge generation layers 32 of the adjacent light-emitting elements 3 being in contact with each other may cause charge leakage from the charge generation layers 32, and the crosstalk between the light-emitting elements 3 caused by the charge leakage may reduce the luminous quality of the display panel. The adjacent charge generation layers 32 are insulated by arranging the first insulation layer 211 to space apart the charge generation layers 32 of the adjacent light-emitting elements 3.

In some embodiments, the isolation structure 2 arranged to space apart adjacent light-emitting elements 3 is a non-light-transmitting structure, to prevent the light emitted by a light-emitting element 3 from entering an adjacent light-emitting element 3.

In some embodiments, the area of an orthographic projection of a surface, away from the substrate 1, of the second part 22 on the substrate 1 is less than the area of an orthographic projection of a surface, close to the substrate 1, of the second part 22 on the substrate 1.

The second part 22 extends outwardly relative to the first part 21 by a predetermined distance, that is, the area of the orthographic projection of the surface, away from the substrate 1, of the second part 22 on the substrate 1 is less than the area of the orthographic projection of the surface, close to the substrate 1, of the second part 22 on the substrate 1, and the second part 22 has an inclined ramp structure, to define a pattern of the light-emitting functional layer by means of the second part 22.

In some embodiments, the cross-sectional area of the second part 22 gradually decreases in a direction away from the substrate 1.

In one embodiment, the cross-section of the second part 22 is in the shape of a trapezoid with a bottom base facing the substrate 1, and the second part 22 has a ramp surface, facilitating the breakage of a preparation material at a partition edge, allowing part of the preparation material to be located on the second part 22 and part of the preparation material to be located in the defining opening 23.

In some embodiments, the area of an orthographic projection of a surface, away from the substrate 1, of the first part 21 on the substrate 1 is less than the area of the orthographic projection of the surface, close to the substrate 1, of the second part 22 on the substrate 1.

That is, the second part 22 extends out relative to the first part 21 to limit the first electrode and the pattern of the light-emitting functional layer by means of the second part 22. The second part 22 has an area greater than that of the first part 21 and covers the entirety of the first part 21. In this case, the first part 21 is recessed relative to the second part 22 in a direction away from the defining opening 23. When the second electrode layer 5 is prepared, the second electrode layer 5 has a large drop at an edge of the isolation structure 2, and the first part 21 is recessed, and the second electrode layer 5 is difficult to be continuous on an outer side of the isolation structure 2, and accordingly breakage occurs, to form the second electrode portions 51 which are isolated from each other.

In some embodiments, the above-mentioned first conductive layer 212 includes a single-layer metal structure. For example, the first conductive layer 212 may include only one layer of aluminum, and a side surface of the aluminum is in lap joint with the second electrode layer 5.

In one embodiment, according to an actual requirement, the first conductive layer 212 may include a multilayer metal structure. For example, the first conductive layer 212 may include a first sub-portion and a second sub-portion which are arranged in a stacked manner. The first sub-portion includes molybdenum and/or titanium, and the second sub-portion includes aluminum.

In one embodiment, the etching rate of the molybdenum or the titanium is low and the first sub-portion extends outwardly relative to the second sub-portion, and the cross-section of the first part 21 is in a trapezoidal shape to facilitate the lap joint with the first electrode formed by means of evaporation. If the first sub-portion and the second part 22 are both prepared from titanium metal, the preparation process can be simplified.

In some embodiments, the cross-sectional area of the first part 21 gradually decreases in the direction away from the substrate 1.

The cross-section of the first part 21 may be in a trapezoidal shape to increase the size of the defining opening 23. The cross-section of the first part 21 may be in the shape of a right trapezoid, and the second part 22 can be securely supported, and the first sub-portion and the second part 22 have a small contact surface area. It is thus achieved that the first part 21 is inwardly recessed relative to the second part 22 in a direction away from the central axis of the defining opening 23, to facilitate the breakage of the second electrode layer 5 and the light-emitting functional layer at the isolation structure 2.

In one embodiment, the orthographic projection of the second part 22 on the substrate 1 coincides with an orthographic projection of the first sub-portion on the substrate 1. The first sub-portion and the second part 22 which have the same area can be etched by using the same mask, and the preparation process is simplified.

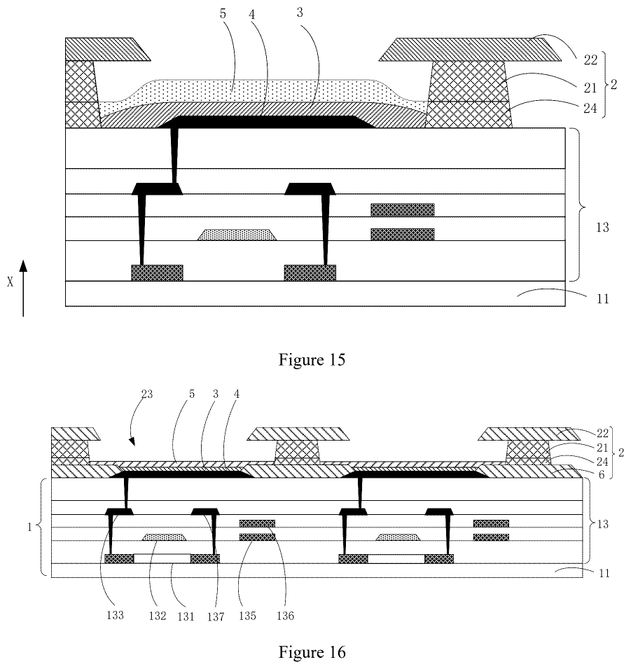

Referring to FIG. 15, in some embodiments, the isolation structure 2 includes a third part 24. The third part 24 is located on a side of the first part 21 close to the substrate 1, and the orthographic projection of the first part 21 on the substrate 1 is located within an orthographic projection of the third part 24 on the substrate 1.

In these embodiments, in order to obtain the inwardly recessed first part 21, the first part 21 has a higher etching rate relative to the second part 22 and/or the third part 24 during etching, and thus the inwardly recessed first part 21 is formed. Since the etching rate of the first part 21 is higher, more waste is generated during the etching and is likely to enter other locations of the display panel, thus causing an adverse effect. By setting the orthographic projection of the first part 21 on the substrate 1 to be located within the orthographic projection of the third part 24 on the substrate 1, the first part 21 can be better supported on the third part 24, and the generated etching waste falls on the third part 24 to facilitate removal.

In some embodiments, the third part 24 is electrically connected to the second electrode layer 5.

The third part 24 may be partially or wholly prepared by a conductive material, and the third part 24 can be electrically connected to the second electrode layer 5, and the third part 24 can provide a required drive voltage for the second electrode layer 5.

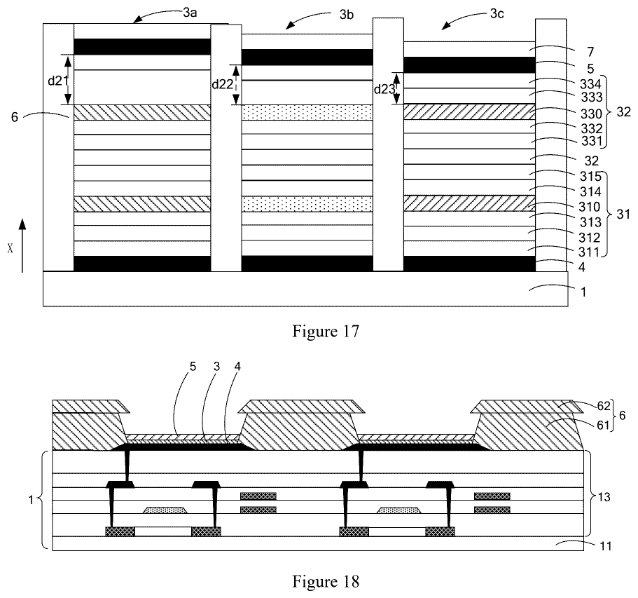

Referring to FIGS. 16 and 17, an embodiment of the disclosure further provides a display panel, which includes a substrate 1, a first electrode layer 4, a second electrode layer 5 and a light-emitting functional layer. The first electrode layer 4 and the second electrode layer 5 are arranged on one side of the substrate 1 and are disposed opposite each other in the first direction X. The light-emitting functional layer includes a pixel defining layer 6 and a plurality of light-emitting elements 3 arranged at intervals. The pixel defining layer 6 has pixel openings. The light-emitting element 3 is at least partially arranged in the pixel opening. The light-emitting element 3 includes a first stacked structure 31, a charge generation layer 32 and a second stacked structure 33, the first electrode layer 4, the first stacked structure 31, the charge generation layer 32, the second stacked structure 33 and the second electrode layer 5 are arranged in sequence, the first stacked structure 31 includes a first light-emitting layer 310, and the second stacked structure 33 includes a second light-emitting layer 330. The plurality of light-emitting elements 3 include a first light-emitting element 3 and a second light-emitting element 3, the first light-emitting layer 310 and the second light-emitting layer 330 of the first light-emitting element 3a are configured to emit a first color of light, and the first light-emitting layer 310 and the second light-emitting layer 330 of the second light-emitting element 3b are configured to emit a second color of light.

A minimum distance between a surface of the second light-emitting layer 330 of the first light-emitting element 3 that is away from the substrate 1 and the second electrode layer 5 is represented by d21, and a minimum distance between a surface of the second light-emitting layer 330 of the second light-emitting element 3 that is away from the substrate 1 and the second electrode layer 5 is represented by d22, where d21≠d22.

By providing the first light-emitting layer 310 and the second light-emitting layer 330, a single light-emitting element 3 has a prolonged luminous lifetime and increased luminous brightness; and by providing the isolation structure 2, arranging the first part 21 of the isolation structure 2 on the side of the second part 22 of the isolation structure 2 that is close to the substrate 1, and making the orthographic projection of the first part 21 on the substrate 1 within the orthographic projection of the second part 22 on the substrate 1, the first stacked structure 31, the charge generation layer 32 and the second stacked structure 33 can be prepared without using metal masks, and the procedure and cost of the metal masks are omitted, a preparation process for the display panel is optimized, the production efficiency of the display panel is improved, and the production cost of the display panel is reduced. Since the light-emitting elements 3 for emitting light of different colors are prepared by means of the isolation structure 2, the light-emitting elements 3 having different properties can be obtained by setting d21≠d22.

In some embodiments, the first light-emitting layer 310 and the second light-emitting layer 330 of the first light-emitting element 3 are configured to emit red light, and the first light-emitting layer 310 and the second light-emitting layer 330 of the second light-emitting element 3 are configured to emit green light, where d21>d22.

When the second light-emitting layer 330 is configured to emit the red light, the minimum distance d21 between the surface of the second light-emitting layer 330 away from the substrate 1 and the second electrode layer 5 is in the range of 25-60 nm. Compared with the second light-emitting layer 330 configured to emit the green light, the blue light or other non-red light, d21 for the second light-emitting layer 330 configured to emit the red light being correspondingly set to be larger facilitates an improvement in the luminous efficiency of the red light.

In some embodiments, the plurality of light-emitting elements 3 further include a third light-emitting element 3, the first light-emitting layer 310 and the second light-emitting layer 330 of the third light-emitting element 3c are configured to emit a third color of light, and a minimum distance between a surface of the second light-emitting layer 330 of the third light-emitting element 3c that is away from the substrate 1 and the second electrode layer 5 is represented by d23, where d21>d22>d23.

Since the wavelength of the red light, the wavelength of the green light and the wavelength of the blue light decrease in sequence, the microcavity effects for the red light, the green light and the blue light can be achieved by correspondingly setting d21>d22>d23.

In some embodiments, d21 is in the range of 25-60 nm.

In some embodiments, d22 is in the range of 20-50 nm.

in some embodiments, d23 is in the range of 15-45 nm.

The different luminous efficiencies can be obtained by changing the distances between the second electrode layer 55 and the second light-emitting layers 330 for respectively emitting the red light, the green light and the blue light. When the second light-emitting layer 330 is configured to emit the red light, d21 is in the range of 25-60 nm, and the second light-emitting layer 330 has good luminous efficiency. When the second light-emitting layer 330 is configured to emit the green light, d22 is in the range of 20-50 nm, and the second light-emitting layer 330 has good luminous efficiency. When the second light-emitting layer 330 is configured to emit the blue light, d23 is in the range of 15-45 nm, and the first light-emitting layer 310 has good luminous efficiency.

In some embodiments, the display panel further includes an isolation structure 2. The isolation structure 2 is arranged on a side of the pixel defining layer 6 away from the substrate 1, and the isolation structure 2 encloses a plurality of defining openings 23. An orthographic projection of the defining opening 23 on the substrate 1 at least partially overlaps with an orthographic projection of the pixel opening on the substrate 1. The isolation structure 2 includes a first part 21 and a second part 22 that are arranged in a stacked manner. The first part 21 is arranged on a side of the second part 22 close to the substrate 1, and an orthographic projection of the first part 21 on the substrate 1 is located within an orthographic projection of the second part 22 on the substrate 1.

by providing the isolation structure 2, arranging the first part 21 of the isolation structure 2 on the side of the second part 22 of the isolation structure 2 that is close to the substrate 1, and making the orthographic projection of the first part 21 on the substrate 1 within the orthographic projection of the second part 22 on the substrate 1, the first stacked structure 31, the charge generation layer 32 and the second stacked structure 33 can be prepared without using metal masks, and the procedure and cost of the metal masks are omitted, a preparation process for the display panel is optimized, the production efficiency of the display panel is improved, and the production cost of the display panel is reduced.

The isolation structure 2 includes a third part 24. The third part 24 is located on a side of the first part 21 close to the substrate, and the orthographic projection of the first part 21 on the substrate 1 is located within an orthographic projection of the third part 24 on the substrate 1.

By setting the orthographic projection of the first part 21 on the substrate 1 to be located within the orthographic projection of the third part 24 on the substrate 1, the first part 21 can be better supported on the third part 24, and the generated etching waste falls on the third part 24 to facilitate removal.

Referring to FIG. 18, the disclosure further provides a display panel, which includes a substrate 1, a first electrode layer 4, a second electrode layer 5, a pixel defining layer 6, and a light-emitting functional layer. The first electrode layer 4 and the second electrode layer 5 are arranged on one side of the substrate 1 and are disposed opposite each other in the first direction X. The pixel defining layer 6 has pixel openings, and the pixel defining layer 6 includes a fourth part 61 and a fifth part 62 that are arranged in a stacked manner. The fourth part 61 is arranged on a side of the fifth part 62 close to the substrate 1, and an orthographic projection of the fourth part 61 on the substrate 1 is located within an orthographic projection of the fifth part 62 on the substrate 1. The light-emitting functional layer includes a plurality of light-emitting elements 3 arranged at intervals. The light-emitting element 3 is at least partially arranged in the pixel opening, and the light-emitting element 3 includes a first stacked structure 31, a charge generation layer 32, and a second stacked structure 33. The first electrode layer 4, the first stacked structure 31, the charge generation layer 32, the second stacked structure 33 and the second electrode layer 5 are arranged in sequence.

By providing the first light-emitting layer 310 and the second light-emitting layer 330, a single light-emitting element 3 has a prolonged luminous lifetime and increased luminous brightness; and by arranging the fourth part 61 of the pixel defining layer 6 on the side of the fifth part 62 of the isolation structure 2 that is close to the substrate 1, and making the orthographic projection of the fourth part 61 on the substrate 1 within the orthographic projection of the fifth part 62 on the substrate 1, the first stacked structure 31, the charge generation layer 32 and the second stacked structure 33 can be prepared without using metal masks, and the procedure and cost of the metal masks are omitted, a preparation process for the display panel is optimized, the production efficiency of the display panel is improved, and the production cost of the display panel is reduced. Since the light-emitting elements 3 for emitting light of different colors are prepared by means of the pixel defining layer 6, the thicknesses of layer structures of the light-emitting elements 3 for emitting light of different colors can be adjusted as required to obtain the light-emitting elements 3 having different properties.

The display panel of the embodiments of the disclosure further include a touch structure layer, a support layer and a cover plate that are arranged on a side of the capping layer away from the substrate. With regard to the specific structures of the touch structure layer, the support layer and the cover plate, reference may be made to conventional configurations in the art, which are not limited by the disclosure.

An embodiment in a third aspect of the disclosure further provides a display device, which includes a display panel according to any one of the above embodiments in the first aspect, or includes a display panel prepared according to any one of the above embodiments in the second aspect, or includes a display panel prepared according to any one of the above embodiments in the third aspect. Since the display device according to the embodiment in the third aspect of the disclosure includes the display panel according to any one of the above embodiments in the first aspect, the second aspect and the third aspect, the display device according to the embodiment in the third aspect of the disclosure has the beneficial effects of the display panel according to any one of the above embodiments in the first aspect, the second aspect and the third aspect, which will not be repeated herein.

An embodiment of the disclosure further provides a preparation method for a display panel. The preparation method includes the following steps.

In step S110, a substrate is provided.

In step S120, a first electrode layer and an isolation structure are formed on one side of the substrate. The isolation structure encloses a plurality of defining openings. The isolation structure includes a first part and a second part that are arranged in a stacked manner. The first part is arranged on a side of the second part close to the substrate, and an orthographic projection of the first part on the substrate is located within an orthographic projection of the second part on the substrate.

In step S130, a light-emitting functional layer and a second electrode layer on one side of the light-emitting functional layer are formed by means of the isolation structure. The light-emitting functional layer includes a plurality of light-emitting elements arranged at intervals. The light-emitting unit is at least partially arranged in the defining opening, and the light-emitting element includes a first stacked structure, a charge generation layer and a second stacked structure. The first electrode layer, the first stacked structure, the charge generation layer, the second stacked structure and the second electrode layer are arranged in sequence.

In step S110, the substrate may specifically be formed by means of coating, curing film formation and other processes. The substrate may be a hard substrate, for example, a glass substrate; or may be a flexible substrate, which may be made of polyimide, polystyrene, polyethylene terephthalate, poly-p-xylylene, polyethersulfone or polyethylene naphthalate. The substrate is configured to mainly support a device arranged thereon.

In step S120, a conductive material for forming the first electrode layer may be first provided on the substrate, and the conductive material may be patterned to obtain the plurality of first electrode portions arranged at intervals. The pixel defining layer is then prepared by using an inorganic material, and the pixel defining layer is etched to form pixel openings and the first electrode portions are exposed from the pixel openings. The isolation structure is then prepared on the pixel defining layer.

The isolation structure may be prepared by first forming a first part material layer and a second part material layer in sequence on one side of the substrate and then etching the second part material layer to form the second part and the first part.

Specifically, the first part material layer and the second part material layer may be etched respectively by using at least one of a dry etching process and a wet etching process, and it should be understood that the specific materials of the first part material layer and the second part material layer are etched by using corresponding etching solvents which are not specially limited.

In step S130, film layers of the light-emitting functional layer, such as an electron injection layer, an electron transport layer, a hole blocking layer, a light-emitting material layer, an electron blocking layer, a hole transport layer and a hole injection layer, and the second electrode layer may be formed by means of evaporation process.

In some embodiments, the defining openings include a first opening and a second opening. Step S130 includes the following steps.

In step S210, a first light-emitting element for emitting a first color of light and the second electrode layer are formed in each defining opening.

In step S220, a removal process is performed on the first light-emitting element and the second electrode layer in the second opening and the first electrode layer is exposed from the second opening.

In step S230, a second light-emitting element for emitting a second color of light and the second electrode layer are formed in each defining opening.

In step S240, a removal process is performed on the second light-emitting element and the second electrode layer, which is located on the second light-emitting element away from the substrate, in the first opening and the first electrode layer located on the first light-emitting element away from the substrate is exposed from the first opening.

In an embodiment provided by the disclosure, the first light-emitting element and the corresponding second electrode portion are first prepared, and the second light-emitting element and the corresponding second electrode portion are then prepared.

The material located in the first opening forms the first light-emitting element and the second electrode portion connected to each other, and the material located in the second opening forms the second light-emitting element and the second electrode portion connected to each other. If there are more than two light-emitting elements for emitting light of different colors, reference may also be made to steps S210-S240, different materials are evaporated stepwise in a third opening, a fourth opening, a fifth opening and so on, and one light-emitting element for emitting light and the second electrode portion are retained in the defining opening by means of the removal process.

In some embodiments, after step S210, the method may further include the following step:
forming a capping layer on a side of the second electrode layer away from the first light-emitting element.

Step S220 includes the following step:
performing a removal process on the second light-emitting element, the second electrode layer and the capping layer 7 in the second opening, and the first electrode layer is exposed from the second opening.

The display device in the embodiments of the disclosure includes, but is not limited to apparatuses having a display function, such as a cell phone, a personal digital assistant (PDA), a tablet computer, an e-book, a television, an access control, a smart fixed-line telephone, or a control console.

The embodiments of the disclosure as described above neither set forth all the details, nor do they limit the disclosure to only the described specific embodiments. Apparently, many modifications and variations can be made in light of the above description. The embodiments are selected and described in this specification to better explain the principles and practical applications of the disclosure. The disclosure is limited only by the claims and all the scopes and equivalents thereof.

1. A display panel, comprising:
a substrate;
a first electrode layer and a second electrode layer arranged on one side of the substrate and disposed opposite each other in a first direction;
an isolation structure arranged on one side of the substrate and enclosing a plurality of defining openings, the isolation structure comprising a first part and a second part that are arranged in a stacked manner, the first part being arranged on a side of the second part close to the substrate, and an orthographic projection of the first part on the substrate being located within an orthographic projection of the second part on the substrate; and
a light-emitting functional layer comprising a plurality of light-emitting elements arranged at intervals, the light-emitting element being at least partially arranged in the defining opening and comprising a first stacked structure, a charge generation layer and a second stacked structure, and the first electrode layer, the first stacked structure, the charge generation layer, the second stacked structure and the second electrode layer being arranged in sequence.

2. The display panel according to claim 1, wherein the first stacked structure comprises a first light-emitting layer, the second stacked structure comprises a second light-emitting layer, the plurality of light-emitting elements comprise a first light-emitting element and a second light-emitting element, the first light-emitting layer and the second light-emitting layer of the first light-emitting element are configured to emit a first color of light, and the first light-emitting layer and the second light-emitting layer of the second light-emitting element are configured to emit a second color of light;
the first light-emitting element has a thickness H1 in the first direction, and the second light-emitting element has a thickness H2 in the first direction, where H1≠H2; and
the first direction is perpendicular to a surface of the substrate.

3. The display panel according to claim 2, wherein the plurality of light-emitting elements further comprise a third light-emitting element, the first light-emitting layer and the second light-emitting layer of the third light-emitting element are configured to emit a third color of light, and the third light-emitting element has a thickness H3 in the first direction, where H1, H2 and H3 are not equal; and
the first light-emitting layer and the second light-emitting layer of the first light-emitting element are configured to emit red light, the first light-emitting layer and the second light-emitting layer of the second light-emitting element are configured to emit green light, and the first light-emitting layer and the second light-emitting layer of the third light-emitting element are configured to emit blue light, where H1>H2>H3.

4. The display panel according to claim 3, wherein the light-emitting element located between the first electrode layer and the second electrode layer forms a microcavity structure, and the light-emitting element satisfies the following formula:
$$m * 2 π = {ϕ}_{b} + {ϕ}_{t} + ( \frac{4 π * n * H}{λ} )$$
where m≥2, m represents a positive integer, ϕ_{b} represents a reflection phase shift of the first electrode layer, ϕₜ represents a reflection phase shift of the second electrode layer, H represents the thickness of the light-emitting element in the first direction, λ represents a wavelength of emitted light of the light-emitting element, and n represents a refractive index of the light-emitting element, m=2 for the microcavity structures formed by the first light-emitting element, the second light-emitting element and the third light-emitting element.

5. The display panel according to claim 3, wherein m≥3 for a microcavity structure formed by at least one of the first light-emitting element, the second light-emitting element and the third light-emitting element.

6. The display panel according to claim 3, wherein a minimum distance between a surface of the first light-emitting layer of the first light-emitting element that is close to the substrate and the first electrode layer is represented by d11, and a minimum distance between a surface of the first light-emitting layer of the second light-emitting element that is close to the substrate and the first electrode layer is represented by d12, where d11≠d12;
a minimum distance between a surface of the first light-emitting layer of the third light-emitting element that is close to the substrate and the first electrode layer is represented by d13, where d11≠d12≠d13; and
the first light-emitting layer and the second light-emitting layer of the first light-emitting element are configured to emit the red light, the first light-emitting layer and the second light-emitting layer of the second light-emitting element are configured to emit the green light, and the first light-emitting layer and the second light-emitting layer of the third light-emitting element are configured to emit the blue light, where d11>d12>d13.

7. The display panel according to claim 5, wherein the first stacked structure comprises a plurality of first functional layers, the plurality of first functional layers comprising a first differential functional layer located on a side of the first light-emitting layer close to or away from the substrate, the first differential functional layer of the first light-emitting element having a thickness H4 in the first direction, and the first differential functional layer of the second light-emitting element having a thickness H5 in the first direction, where H4≠H5;
the first differential functional layer is the first emitting prime layer, the first emitting prime layer of the first light-emitting element has a thickness d61, a first hole transport layer of the second light-emitting element has a thickness d62, and the first hole transport layer of the third light-emitting element has a thickness d63, where d61>d62>d63; or
the first differential functional layer is the first hole transport layer, the first hole transport layer of the first light-emitting element has a thickness d31, the first hole transport layer of the second light-emitting element has a thickness d32, and the first hole transport layer of the third light-emitting element has a thickness d33, where d31>d32>d33.

8. The display panel according to claim 2, wherein a minimum distance between a surface of the second light-emitting layer of the first light-emitting element that is away from the substrate and the second electrode layer is represented by d21, and a minimum distance between a surface of the second light-emitting layer of the second light-emitting element that is away from the substrate and the second electrode layer is represented by d22, where d21≠d22;
the plurality of light-emitting elements further comprise a third light-emitting element, the first light-emitting layer and the second light-emitting layer of the third light-emitting element are configured to emit a third color of light, and a minimum distance between a surface of the second light-emitting layer of the third light-emitting element that is away from the substrate and the second electrode layer is represented by d23, where d21≠d22≠d23.

9. The display panel according to claim 8, wherein the second stacked structure comprises a plurality of second functional layers, the plurality of second functional layers comprising a second differential functional layer located on a side of the second light-emitting layer close to or away from the substrate, the second differential functional layer of the first light-emitting element having a thickness H6 in the first direction, and the second differential functional layer of the second light-emitting element having a thickness H7 in the first direction, where H6≠H7;
the second differential functional layer is a second electron transport layer, the second electron transport layer of the first light-emitting element has a thickness d41, the second electron transport layer of the second light-emitting element has a thickness d42, and the electron transport layer of the third light-emitting element has a thickness d43, where d41>d42>d43; or
the second differential functional layer is a second hole blocking layer, the second hole blocking layer of the first light-emitting element has a thickness d71, the second hole blocking layer of the second light-emitting element has a thickness d72, and the second hole blocking layer of the third light-emitting element has a thickness d73, where d71>d72>d73.

10. The display panel according to claim 3, wherein the charge generation layer of the first light-emitting element has a thickness d51, the charge generation layer of the second light-emitting element has a thickness d52, and the charge generation layer of the third light-emitting element has a thickness d53, where d51≠d52≠d53.

11. The display panel according to claim 1, wherein a surface of the first electrode layer away from the substrate is a reflective surface, the second electrode layer comprises a plurality of second electrode portions, and the plurality of second electrode portions are semi-reflective and semi-transmissive electrodes;
the plurality of light-emitting elements comprise a first light-emitting element and a second light-emitting element, the first stacked structure comprises a first light-emitting layer, the second stacked structure comprises a second light-emitting layer, the first light-emitting layer and the second light-emitting layer of the first light-emitting element are configured to emit a first color of light, the first light-emitting layer and the second light-emitting layer of the second light-emitting element are configured to emit a second color of light, the second electrode portion located on one side of the first light-emitting element has a thickness H8 in the first direction, and the second electrode portion located on one side of the second light-emitting element has a thickness H9 in the first direction, where H8≠H9.

12. The display panel according to claim 1, wherein the display panel further comprises a capping layer located on a side of the second electrode layer away from the substrate, the capping layer being at least partially arranged in the defining opening;
the plurality of light-emitting elements comprise a first light-emitting element and a second light-emitting element, the first stacked structure comprises a first light-emitting layer, the second stacked structure comprises a second light-emitting layer, the first light-emitting layer and the second light-emitting layer of the first light-emitting element are configured to emit a first color of light, the first light-emitting layer and the second light-emitting layer of the second light-emitting element are configured to emit a second color of light, the capping layer located on one side of the first light-emitting element has a thickness H10 in the first direction, and the capping layer located on one side of the second light-emitting element has a thickness H11 in the first direction, where H10≠H11; and
the plurality of light-emitting elements further comprise a third light-emitting element, the first light-emitting layer and the second light-emitting layer of the third light-emitting element are configured to emit a third color of light, and the capping layer located on one side of the third light-emitting element has a thickness H12 in the first direction, where H10>H11>H12.

13. The display panel according to claim 1, wherein the display panel further comprises a filter layer located on a side of the second electrode layer away from the substrate and comprising a plurality of filter portions, an orthographic projection of the plurality of filter portions on the substrate overlapping with an orthographic projection of the light-emitting functional layer on the substrate; and
the filter layer further comprises a light blocking portion arranged to space apart adjacent filter portions, an orthographic projection of the light blocking portion on the substrate falling within an orthographic projection of the isolation structure on the substrate.

14. The display panel according to claim 1, wherein the isolation structure further comprises a pixel defining layer arranged on a side of the first part away from the second part, the pixel defining layer comprising a plurality of pixel openings, and the light-emitting element being at least partially arranged in the pixel opening; and
the display panel further comprises an encapsulation layer located on a side of the second electrode layer away from the substrate, an edge of the encapsulation layer being at least in lap joint with the isolation structure, or the encapsulation layer covering a side of the isolation structure away from the substrate.

15. The display panel according to claim 1, wherein the isolation structure is in a form of a grid, and is arranged to space apart adjacent light-emitting elements;
the first part is electrically connected to the second electrode layer;
an area of an orthographic projection of a surface, away from the substrate, of the second part on the substrate is less than the area of an orthographic projection of a surface, close to the substrate, of the second part on the substrate;
a cross-sectional area of the second part gradually decreases in a direction away from the substrate;
the area of an orthographic projection of a surface, away from the substrate, of the first part on the substrate is less than the area of the orthographic projection of the surface, close to the substrate, of the second part on the substrate;
wherein the cross-sectional area of the first part gradually decreases in the direction away from the substrate;
the isolation structure comprises a third part located on a side of the first part close to the substrate, and the orthographic projection of the first part on the substrate is located within an orthographic projection of the third part on the substrate; and
wherein the third part is electrically connected to the second electrode layer.

16. A display panel, comprising:
a substrate;
a first electrode layer and a second electrode layer arranged on one side of the substrate and disposed opposite each other in a first direction;
a light-emitting functional layer comprising a pixel defining layer and a plurality of light-emitting elements arranged at intervals, the pixel defining layer comprising a plurality of pixel openings, and the plurality of light-emitting elements being at least partially arranged in the pixel openings, wherein at least one of the plurality of light-emitting element comprises a first stacked structure, a charge generation layer and a second stacked structure, the first electrode layer, the first stacked structure, the charge generation layer, the second stacked structure and the second electrode layer are arranged in sequence, the first stacked structure comprises a first light-emitting layer, and the second stacked structure comprises a second light-emitting layer; the plurality of light-emitting elements comprises a first light-emitting element and a second light-emitting element, the first light-emitting layer and the second light-emitting layer of the first light-emitting element are configured to emit a first color of light, and the first light-emitting layer and the second light-emitting layer of the second light-emitting element are configured to emit a second color of light; and
a minimum distance between a surface of the second light-emitting layer of the first light-emitting element that is away from the substrate and the second electrode layer is represented by d21, and a minimum distance between a surface of the second light-emitting layer of the second light-emitting element that is away from the substrate and the second electrode layer is represented by d22, where d21≠d22.

17. The display panel according to claim 16, wherein the first light-emitting layer and the second light-emitting layer of the first light-emitting element are configured to emit red light, and the first light-emitting layer and the second light-emitting layer of the second light-emitting element are configured to emit green light, where d21>d22;
the plurality of light-emitting elements further comprise a third light-emitting element, the first light-emitting layer and the second light-emitting layer of the third light-emitting element are configured to emit a third color of light, and a minimum distance between a surface of the second light-emitting layer of the third light-emitting element that is away from the substrate and the second electrode layer is represented by d23, where d21>d22>d23;
d21 is in a range of 25-60 nm;
d22 is in a range of 20-50 nm; and
d23 is in a range of 15-45 nm.

18. The display panel according to claim 17, wherein the display panel further comprises an isolation structure, the isolation structure being arranged on a side of the pixel defining layer away from the substrate, and enclosing a plurality of defining openings, an orthographic projection of the defining opening on the substrate at least partially overlapping with an orthographic projection of the pixel opening on the substrate, and the isolation structure comprising a first part and a second part that are arranged in a stacked manner, wherein the first part is arranged on a side of the second part close to the substrate, and an orthographic projection of the first part on the substrate is located within an orthographic projection of the second part on the substrate; and
the isolation structure comprises a third part is located on a side of the first part close to the substrate, the orthographic projection of the first part on the substrate being located within an orthographic projection of the third part on the substrate.

19. A display panel, comprising:
a substrate;
a first electrode layer and a second electrode layer arranged on one side of the substrate and disposed opposite each other in a first direction;
a pixel defining layer arranged on one side of the substrate and comprising a plurality of pixel openings, the pixel defining layer comprising a fourth part and a fifth part that are arranged in a stacked manner, the fourth part being arranged on a side of the fifth part close to the substrate, and an orthographic projection of the fourth part on the substrate being located within an orthographic projection of the fifth part on the substrate; and
a light-emitting functional layer comprising a plurality of light-emitting elements arranged at intervals, the light-emitting element being at least partially arranged in the pixel opening and comprising a first stacked structure, a charge generation layer and a second stacked structure, and the first electrode layer, the first stacked structure, the charge generation layer, the second stacked structure and the second electrode layer being arranged in sequence.

20. A display device, comprising a display panel according to claim 1.
